(19) United States
(12) Patent Application Publication
(10) Pub. No.: US 2020/0098995 A1
(43) Pub. Date: Mar. 26, 2020

(54) POLYMER AND ELECTROLUMINESCENT DEVICE

(71) Applicant: GUANGZHOU CHINARAY OPTOELECTRONIC MATERIALS LTD., Guangzhou, Guangdong (CN)

(72) Inventors: Junyou PAN, Guangzhou, Guangdong (CN); Jiahui TAN, Guangzhou, Guangdong (CN)

(73) Assignee: GUANGZHOU CHINARAY OPTOELECTRONIC MATERIALS LTD., Guangzhou, Guangdong (CN)

(21) Appl. No.: 16/467,417

(22) PCT Filed: Dec. 8, 2017
(86) PCT No.: PCT/CN2017/115311

§ 371 Date: Jun. 6, 2019

(30) Foreign Application Priority Data
Dec. 8, 2016 (CN) 201611123281.5

(51) Int. Cl. H01L 51/00; C09K 11/06

(52) U.S. Cl. CPC H01L 51/0072; H01L 51/5056; C09K 11/06

(57) ABSTRACT

An electroluminescent device includes an anode, a cathode, a light emitting layer between the anode and the cathode, and a hole transport layer between the anode and the light emitting layer. The light emitting layer includes an inorganic light emitting nanomaterial, and the hole transport layer includes an organic hole transport material. The organic hole transport material has HOMO_{HTM}≤−5.4 eV and □(HOMO−1)_{HTM}−HOMO_{HTM}□≥0.3 eV.

### TECHNICAL FIELD

The present disclosure relates to the field of electroluminescence, particularly to a polymer and an electroluminescent device.

### BACKGROUND

Lighting and display are major demands for human society, and their energy consumption is a large part of current social energy consumption. Therefore, people are constantly seeking for new energy-saving and environmental protection technologies. Wherein light-emitting diode (LEDs) is gradually replacing traditional lighting materials to become a new generation of lighting sources due to their advantages of energy saving, environmental protection and durability. However, currently the thin film deposition technique adopted by commercial LEDs has high requirements in vacuum and the production cost is high, which make it difficult to realize large-area and flexible substrate production. Although organic light-emitting diodes (OLEDs) are used as a new generation of lighting and display technology which enable large-area device production, device lifetime still needs to be improved. At the same time, the half-peak width of the electroluminescence spectrum of OLED is over 40 nm, which is not conducive to its application in display equipment. In addition, the problems of efficiency roll-off and lifetime reduction of OLED under high brightness also limit the application in solid-state lighting.

Currently, a quantum dot light-emitting diode (QLED) which is an electroluminescent device based on quantum dot technology has been proposed. Compared to the traditional display technology, QLED can adjust the emission wavelength by changing the size of the quantum dots in the light-emitting layer or changing its composition, meanwhile the half-peak width of the quantum dot luminescence spectrum is generally less than 30 nm, which can realize display with high color gamut and white-light illumination with high color rendering index, and can be produced in large area on a flexible substrate by solution processing, which can greatly reduce production costs. Therefore, quantum dot light-emitting diode (QLED) is a promising next-generation of display and solid-state lighting source.

Although QLEDs have the above advantages, the research of QLEDs is still in its infancy, and the existing QLEDs have defects such as low luminous efficiency of quantum dots and low lifetime of QLEDs, etc. The existing QLEDs are organic-inorganic composite multilayer devices, comprising a hole transporting layer (HTL), a light-emitting layer (EL), and an electron transporting layer (ETL). Currently, the hole transporting layer of QLED still uses the hole transporting material of OLED, including poly (p-phenylene vinylene) (PPV), poly(9,9-dioctylfluorene-CO—N-(4-butylphenyl)diphenylamine) (TFB), N,N′-diphenyl-N,N′-bis(3-methylphenyl)-1,1′-biphenyl-4,4′-diamine (TPD), the highest occupied molecular orbital energy level of these hole transporting materials does not match the valence band energy level of the quantum dots of the light-emitting layer, so that the hole injection efficiency is relatively low. As a result, the charge injected into the quantum dots in the light-emitting layer is unbalance. The quantum dots are also non-electrically neutral, which greatly reduces the luminescence efficiency of the quantum dots. Although the PVK with deep energy level is used for QLED hole transporting layer, PVK is an unstable HTM material.

### SUMMARY

Accordingly, it is necessary to provide a polymer and an electroluminescent device to solve the problems of luminous efficiency and lifetime of the electroluminescent devices.

An electroluminescent device includes an anode, a cathode, a light-emitting layer located between the anode and the cathode, and a hole transporting layer located between the anode and the light-emitting layer. The light-emitting layer includes an inorganic luminescent nanomaterial, the hole transporting layer includes an organic hole transporting material having a HOMO_{HTM}≤−5.4 eV and □(HOMO-1)_{HTM}−HOMO_{HTM}□≥0.3 eV.

A polymer has at least one of the following structural general formulas:

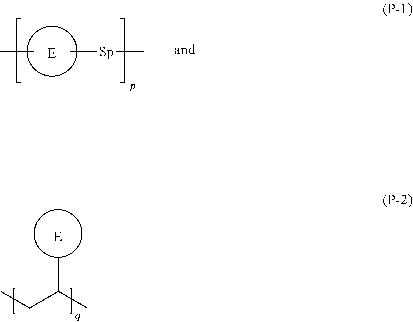

wherein p and q represent the number of repeating units, and both p and q are integers of ≥1;

HOMO_{E}≤−5.4 eV and □(HOMO−1)_{E}−HOMO_{E}□≥0.3 eV;

E is one of the following structures:

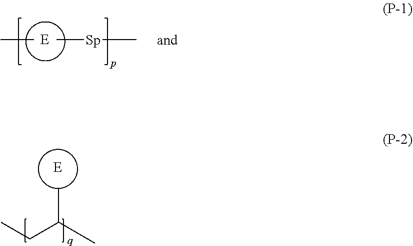

wherein -L₁- is a single bond or an arylene group containing 6 to 30 carbon atoms;

-L⁴- is an aryl group containing 5 to 60 carbon atoms or a heteroaryl group containing 5 to 60 carbon atoms;

-L⁵- is one selected from the group consisting of a single bond, an aryl group containing 5 to 30 carbon atoms, and a heteroaryl group containing 5 to 30 carbon atoms;

A, B, C, and D are each independently an aromatic ring containing 6 to 40 carbon atoms or an heteroaromatic ring containing 5 to 40 carbon atoms;

—X—, —Y—, and —Z— are each independently selected from the group consisting of —NR₁₁—, —CR₁₂R₁₃—, —O—, and —S—;

R₁, R₂, R₁₁, R₁₂ and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms;

m, w, and o are each independently 0 or 1;

Ar³, Ar⁴, Ar⁵, Ar⁶, Ar⁷, and Ar⁸ are each independently selected from an aryl group containing 5 to 40 carbon atoms, and a heteroaryl group containing 5 to 40 carbon atoms;

—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—,

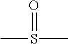

### and —SO₂—;

—X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—,

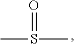

and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously; and in the general formula (IV), at least one of the —X²—, —X³—, —X⁴—, —X⁵—, —X⁶—, —X⁷—, —X⁸—, and —X⁹— is —N(R)—;

R¹, R² and R are each independently selected from the group consisting of H, D, F, CN, alkenyl, alkynyl, nitrile, amine, nitro, acyl, alkoxy, carbonyl, sulfonyl, and an alkyl group containing 1 to 30 carbon atoms, a cycloalkyl group containing 3 to 30 carbon atoms, an aromatic hydrocarbyl group containing 6 to 60 carbon atoms, and an aromatic heterocyclyl group containing 5 to 60 carbon atoms; wherein attachment positions of R¹ and R² are carbon atoms on the fused ring;

n is an integer of 0 to 4;

Sp is a non-conjugated spacer group.

The details of multiple embodiments of the present disclosure are set forth in the the description below. Other features, objects and advantages of the present disclosure will become apparent from the description and the claims.

### DETAILED DESCRIPTION OF THE EMBODIMENTS

The present disclosure provides a polymer and an electroluminescent device. In order to make the purpose, technical solution and effects of the present disclosure clearer and more specific, the present disclosure will be further described in detail below. It should be understood that, the specific embodiment illustrated herein is merely for the purpose of explanation, and should not be deemed to limit the disclosure.

HOMO is defined as the highest occupied molecular orbital energy level, (HOMO−1) is defined as the second highest occupied molecular orbital energy level. LUMO is defined as the lowest unoccupied molecular orbital energy level. That is, HOMO_{HTM} represents the highest occupied molecular orbital energy level of the organic hole transporting material, (HOMO−1)_{HTM} represents the second highest occupied molecular orbital energy level of the organic hole transporting material, and HOMO_{NPB} represents the highest occupied molecular orbital energy level of NPB, LUMO_{HTM} represents the lowest unoccupied molecular orbital energy level of the organic hole transporting material, and so on.

The HOMO and LUMO energy levels can be measured by photoelectric effect, such as XPS (X-ray Photoelectron Spectroscopy) and UPS (Ultraviolet Photoelectron Spectroscopy) or by Cyclic Voltammetry (hereinafter referred to as CV). It also can be calculated by quantum chemistry method, such as the density functional theory (hereinafter referred to as DFT).

It should be noted that, the absolute values of HOMO and LUMO depend on the measurement method or calculation method used, even for the same method, different HOMO/LUMO value may be obtained by different evaluation methods, such as at starting point and peak point on the CV curve. Therefore, reasonable and meaningful comparisons should be made by using same measurement method and same evaluation method. The values of HOMO and LUMO are based on the simulations of Time-dependent DFT, but this does not affect the application of other measurement or calculation methods.

The organic hole transporting material of the present embodiment has a highest occupied molecular orbital energy level HOMO_{HTM}≤−5.4 eV, wherein −5.4 eV is not an absolute value, it is a value relative to the standard material NPB (see the following chemical formula). It should be understood that, according to the method of the present embodiment (see the specific embodiment), the highest occupied molecular orbital energy level of NPB is −5.22 eV, (−5.22)−(−5.4)=0.18 eV. Therefore, accurately, the present embodiment requires that the organic hole transporting material has a highest occupied molecular orbital level HOMO_{HTM}≤HOMO_{NPB}−0.18 eV.

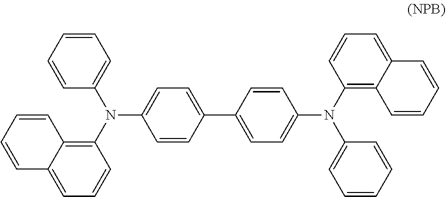 [SMILES: c1ccc(N(c2ccc(-c3ccc(N(c4ccccc4)c4cccc5ccccc45)cc3)cc2)c2cccc3ccccc23)cc1]

The present embodiment relates to small molecule materials or polymer materials.

The term “small molecule” as defined herein refers to a molecule that is not a polymer, oligomer, dendrimer, or blend. There are no repeating structures in small molecules.

Polymer includes homopolymer, copolymer, and block copolymer, additionally in the present embodiment, the polymer also includes a dendrimer. The synthesis and application of dendrimers can be found in Dendrimers and Dendrons, Wiley-VCH Verlag GmbH & Co. KGaA, 2002, Ed. George R. Newkome, Charles N. Moorefield, Fritz Vogtle.

Conjugated polymer is a polymer whose backbone is primarily consisted of the sp2 hybrid orbital of C atoms, such as polyacetylene and poly (phenylene vinylene). The C atoms on the backbones of conjugated polymer may also be substituted by other non-C atoms, and which are still considered to be conjugated polymers when the sp2 hybridization on the backbones is interrupted by some natural defects. In addition, the conjugated polymer in the present embodiment may optionally comprise heteroaromatic, aryl amine, aryl phosphine on the backbone, and may optionally comprise organometallic complexes on the backbone.

An electroluminescent device includes an anode, a cathode, a light-emitting layer located between the anode and the cathode, and a hole transporting layer located between the anode and the light-emitting layer.

In one of the embodiments, the electroluminescent device also includes a substrate on which the anode is laminated.

In one of the embodiments, the electroluminescent device also includes a substrate on which the cathode is laminated. Such structure of the electroluminescent device can promote the electron injection in the quantum dot layer and improve the brightness efficiency of the device.

In one of the embodiments, the substrate may be optionally opaque. In other embodiments, the substrate may be optionally transparent. The transparent substrate can be used to fabricate a luminescent device, which may refers to Bulovic et al. Nature 1996, 380, p 29 and Gu et al. Appl. Phys. Lett. 1996, 68, p 2606 for details.

In one of the embodiments, the substrate may be optionally a rigid substrate, and also be optionally a flexible substrate.

In one of the embodiments, the material of the substrate is one selected from the group consisting of plastic, metal, semiconductor wafer, and glass.

In one of the embodiments, the substrate has a smooth surface.

In one of the embodiments, the material of the substrate may be one selected from the group consisting of the polymer thin film and plastic, the glass transition temperature T_{g} of the substrate is over 150° C.

In one of the embodiments, the glass transition temperature T_{g} of the substrate is greater than 200° C.

In one of the embodiments, the glass transition temperature T_{g} of the substrate is greater than 250° C.

In one of the embodiments, the glass transition temperature T_{g} of the substrate is greater than 300° C.

In one of the embodiments, the substrate is one selected from the group consisting of poly(ethylene terephthalate) (PET) and polyethylene(2,6-naphthalate)(PEN).

The anode material includes one of a conductive metal, a metallic oxide, and a conductive polymer. The anode can inject holes into HIL, HTL and light emitting layer.

In one of the embodiments, the absolute value of the difference between the work function of the anode and the HOMO energy level or the valence band energy level of the p-type semiconductor material as the HIL or HTL is less than 0.5 eV.

In one of the embodiments, the absolute value of the difference between the work function of the anode and the HOMO energy level or the valence band energy level of the p-type semiconductor material as the HIL or HTL is less than 0.3 eV.

In one of the embodiments, the absolute value of the difference between the work function of the anode and the HOMO energy level or the valence band energy level of the p-type semiconductor material as the HIL or HTL is less than 0.2 eV.

In one of the embodiments, the anode material is one selected from the group consisting of Al, Cu, Au, Ag, Mg, Fe, Co, Ni, Mn, Pd, Pt, ITO, and aluminum-doped zinc oxide (AZO). And, the anode material can also be other materials commonly used by those of ordinary skill in the art.

The anode material may be optionally prepared by deposition technique.

In one of the embodiments, the anode material is prepared by physical vapor deposition.

In one embodiment, the anode material is prepared by radio frequency magnetron sputtering, vacuum thermal evaporation, or electron beam (e-beam).

In one of the embodiments, the anode is patterned and structured, and a patterned ITO conductive substrate is commercially available and can be used to prepare the electroluminescent device described above.

The cathode is a conductive metal or metal oxide. The cathode can inject electrons into the EIL or ETL, or directly injected into the light-emitting layer. In one of the embodiments, the absolute value of the difference between the work function of the cathode and the LUMO energy level or the conduction band energy level of the n-type semiconductor material as the EIL or ETL or HBL is less than 0.5 eV.

In one of the embodiments, the difference between the work function of the cathode and the LUMO energy level or the conduction band energy level of the n-type semiconductor material as the EIL or ETL or HBL is less than 0.3 eV.

In one of the embodiments, the difference between the work function of the cathode and the LUMO energy level or the conduction band energy level of the n-type semiconductor material as the EIL or ETL or HBL is less than 0.2 eV.

It will be understood that, all materials that can be used as cathodes for OLED can be used as cathode materials for the electroluminescent devices described above.

In one of the embodiments, the cathode material is one selected from the group consisting of Al, Au, Ag, Ca, Ba, Mg, LiF/Al, MgAg alloy, BaF₂/Al, Cu, Fe, Co, Ni, Mn, Pd, Pt, and ITO.

The cathode material may be optionally prepared by deposition technique.

In one of the embodiments, the cathode material is prepared by physical vapor deposition.

In one embodiment, the cathode material is prepared by radio frequency magnetron sputtering, vacuum thermal evaporation, or electron beam (e-beam).

The light-emitting layer is located between the anode and the cathode, including an inorganic nanomaterial, and the inorganic nanomaterial can be used for quantum luminescence.

In one of the embodiments, the light-emitting layer has a thickness of 2 μm to 200 μm.

In one of the embodiments, the light-emitting layer has a thickness of 5 μm to 100 μm.

In one of the embodiments, the light-emitting layer has a thickness of 15 μm to 80 μm.

In one of the embodiments, the inorganic nanomaterial has an average particle size of 1 nm to 1000 nm.

In one of the embodiments, the inorganic nanomaterial has an average particle size of 1 nm to 100 nm.

In one of the embodiments, the inorganic nanomaterial has an average particle size of 1 nm to 20 nm.

In one of the embodiments, the inorganic nanomaterial has an average particle size of 1 nm to 10 nm.

In one of the embodiments, the inorganic nanomaterial is selected from different shapes including, but not limited to, at least one of sphere, cube, rod, disk, or branched structure.

In one of the embodiments, the inorganic nanomaterial is a quantum dot having very narrow and monodisperse size distribution, i.e., the size difference between the particles and the particles is very small.

In one of the embodiments, the monodisperse quantum dots have a root mean square deviation of less than 15% rms in size.

In one of the embodiments, the monodisperse quantum dots have a root mean square deviation of less than 10% rms in size.

In one of the embodiments, the monodisperse quantum dots have a root mean square deviation of less than 5% rms in size.

In one of the embodiments, the inorganic nanomaterial is a light-emitting material.

In one of the embodiments, the inorganic nanomaterial includes a light-emitting quantum dot material.

In general, quantum dots can emit light at wavelengths between 380 nanometers and 2500 nanometers. For example, the quantum dots with CdS cores have an emission wavelength in the range of about 400 nm to 560 nm; the quantum dots with CdSe cores have an emission wavelength in the range of about 490 nm to 620 nm; the quantum dots with CdTe cores have an emission wavelength in the range of about 620 nm to 680 nm; the quantum dots with InGaP cores have an emission wavelengths in the range of about 600 nanometers to 700 nanometers; the quantum dots with PbS cores have an emission wavelengths in the range of about 800 nanometers to 2500 nanometers; the quantum dots with PbSe cores have an emission wavelength in the range of about 1200 nm to 2500 nm; the quantum dots with CuInGaS cores have an emission wavelength in the range of about 600 nm to 680 nm; the quantum dots with ZnCuInGaS cores have an emission wavelength in the range of about 500 nm to 620 nm; the quantum dots with CuInGaSe cores have an emission wavelength in the range of about 700 nm to 1000 nm.

In one of the embodiments, the quantum dot can emit at least one of blue light with the peak luminous wavelength of 450 nm to 460 nm, green light with the peak luminous wavelength of 520 nm to 540 nm, and red light with the peak luminous wavelength of 615 nm to 630 nm.

The quantum dots can be of particular chemical compositions, morphologies, and/or size dimensions to obtain light with desired wavelength emitted under electric excitation. The relationship between the luminescent properties of quantum dots and their chemical composition, morphologies and/or size dimensions can be found in Annual Review of Material Sci., 2000, 30, 545-610; Optical Materials Express., 2012, 2, 594-628; Nano Res, 2009, 2, 425-447.

The narrow particle size distribution of quantum dots enables quantum dots to have a narrower luminescence spectrum (J. Am. Chem. Soc., 1993, 115, 8706; US 20150108405). In addition, depending on the different chemical composition and structure used, the size of the quantum dots needs to be adjusted within the above-mentioned size range to obtain the luminescent properties of desired wavelength.

The quantum dots include semiconductor nanocrystals. In one of the embodiments, the size of the semiconductor nanocrystals is in the range of 5 nanometers to 15 nanometers. In addition, depending on the different chemical composition and structure used, the size of the quantum dots needs to be adjusted within the above-mentioned size range to obtain the luminescent properties of the desired wavelength.

In one of the embodiments, the quantum dots include nanorods. The properties of the nanorods are different from those of spherical nanograin. For example, the luminescence of the nanorods is polarized along the long rod axis, while the luminescence of the spherical grains is unpolarized (see Woggon et al., Nano Lett., 2003, 3, 509). Nanorods have excellent optical gain characteristics, making them possible to be used as laser gain materials (see Banin et al. Adv. Mater. 2002, 14, 317). In addition, the luminescence of the nanorods can be reversibly turned on and off under the control of an external electric field (see Banin et al, Nano Lett. 2005, 5, 1581). These characteristics of the nanorods can be incorporated into the device of the present embodiment. Examples of preparation of semiconductor nanorods are WO03097904A1, US2008188063A1, US2009053522A1, KR20050121443A.

In one of the embodiments, the quantum dots include at least one semiconductor material, wherein the semiconductor material is at least one selected from semiconductor materials of Group IV, Group II-VI, Group II-V, Group III-V, Group III-VI, Group IV-VI, Group I-III-VI, Group II-IV-VI, and Group II-IV-V of the Periodic Table of the Elements.

In one of the embodiments, the quantum dots include a Group IV semiconductor material.

In one of the embodiments, the quantum dots include at least one of Si, Ge, SiC, and SiGe.

In one of the embodiments, the quantum dots include a Group II-VI semiconductor material.

In one of the embodiments, the quantum dots include at least one selected from the group consisting of a binary Group II-VI semiconductor compound, a ternary Group II-VI semiconductor compound, and a quaternary Group II-VI semiconductor compound. The binary Group II-VI semiconductor compound includes CdSe, CdTe, CdO, CdS, CdSe, ZnS, ZnSe, ZnTe, ZnO, HgO, HgS, HgSe, and HgTe, the ternary Group II-VI semiconductor compound includes CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS, and HgSeSe, and the ternary Group II-VI semiconductor compound includes CgHgSeS, CdHgSeTe, CgHgSTe, CdZnSeS, CdZnSeTe, HgZnSeTe, HgZnSTe, CdZnSTe, and HgZnSeS.

In one of the embodiments, the quantum dots include at least one selected from the group consisting of CdSe, CdS, CdTe, ZnO, ZnSe, ZnS, ZnTe, HgS, HgSe, HgTe, and CdZnSe.

In one of the embodiments, the quantum dots include at least one selected from the group consisting of CdSe and CdS, and the synthesis of CdSe and CdS is relatively mature and the materials are used as light-emitting quantum dots for visible light.

In one of the embodiments, the quantum dots include a Group III-V semiconductor material.

In one of the embodiments, the quantum dots include at least one selected from the group consisting of a binary Group III-V semiconductor compound, a ternary Group III-V semiconductor compound, and a quaternary Group III-V semiconductor compound. The binary Group III-V semiconductor compound includes AlN, AlP, AlAs, AlSb, GaN, GaP, GaAs, GaSb, InN, InP, InAs, and InSb, the ternary Group III-V semiconductor compound includes AlNP, AlNAs, AlNSb, AlPAs, AlPSb, GaNP, GaNAs, GaNSb, GaPAs, GaPSb, InNP, InNAs, InNSb, InPAs, and InPSb, and the quaternary Group III-V semiconductor compound includes GaAlNAs, GaAlNSb, GaAlPAs, GaInNP, GaInNAs, GaInNSb, GaInPAs, GaInPSb, InAlNP, InAlNAs, InAlNSb, InAlPAs and InAlPSb.

In one of the embodiments, the quantum dots include at least one selected from the group consisting of InAs, InP, InN, GaN, InSb, InAsP, InGaAs, GaAs, GaP, GaSb, AlP, AlN, AlAs, AlSb, CdSeTe, and ZnCdSe.

In one of the embodiments, the quantum dots include a Group IV-VI semiconductor material.

In one of the embodiments, the quantum dots include a Group IV-VI semiconductor compound comprising at least one of a binary Group IV-VI semiconductor compound, a ternary Group IV-VI semiconductor compound, and a quaternary Group IV-VI semiconductor compound. The binary Group IV-VI semiconductor compound includes SnS, SnSe, SnTe, PbSe, PbS, and PbTe, the ternary Group IV-VI semiconductor compound includes SnSeS, SnSeTe, SnSTe, SnPbS, SnPbSe, SnPbTe, PbSTe, PbSeS, and PbSeTe, and the quaternary Group IV-VI semiconductor compound includes SnPbSSe, SnPbSeT, and SnPbSTe.

In one of the embodiments, the quantum dots include at least one selected from the group consisting of PbSe, PbTe, PbS, PbSnTe, and Tl₂SnTes.

In one of the embodiments, the quantum dots have core-shell structures. The specific surface area of quantum dots with the pure core structure is relatively large, which is easy to produce some surface defects. Such defects have the ability to capture holes or electrons, which increases the probability of nonradiative recombination, and thus resulting in the degradation of the electrical and optical properties of quantum dots. Bare cores of the quantum dot are sensitive to oxygen and may cause spectral diffusion and fluorescence quenching when exposed to air. For the quantum dots of the core/shell structure, the addition of the shell layer reduces the surface defects of the bare-core quantum dots, thus improving the stability and quantum yield of the quantum dots.

The core and shell of the quantum dots each independently include at least one semiconductor material.

In one of the embodiments, the core of the quantum dots includes at least one selected from the group consisting of a semiconductor material of Group IV, a semiconductor material of Group II-VI, a semiconductor material of Group II-V, a semiconductor material of Group III-V, a semiconductor material of Group III-VI, a semiconductor material of Group IV-VI, a semiconductor material of Group I-III-VI, a semiconductor material of Group II-IV-VI, and a semiconductor material of Group II-IV-V of the periodic table.

In one of the embodiments, the core of the quantum dots includes at least one selected from the group consisting of ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, and Si.

In one of the embodiments, the shell of the quantum dots includes a semiconductor material.

In one of the embodiments, the shell of the quantum dots includes at least one selected from the group consisting of a semiconductor material of Group IV, a semiconductor material of Group II-VI, a semiconductor material of Group II-V, a semiconductor material of Group III-V, a semiconductor material of Group III-VI, a semiconductor material of Group IV-VI, a semiconductor material of Group I-III-VI, a semiconductor material of Group II-IV-VI, and a semiconductor material of Group II-IV-V of the periodic table.

In one of the embodiment, the shell of the quantum dots includes at least one selected from the group consisting of ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, and Si.

In one of the embodiments, the shell of the quantum dots may be optionally a single layer structure, also may be optionally a multilayer structure.

In one of the embodiments, the shell of the quantum dots has a thickness of from 1 to 20 layers, where the thickness of one layer refers to the thickness of the atomic layer of the quantum dot.

In one of the embodiments, the shell of the quantum dots has a thickness of from 5 to 10 layers, where the thickness of one layer refers to the thickness of the atomic layer of the quantum dot.

In one of the embodiments, a shell of two different materials is grown on the surface of the core of the quantum dots.

In one of the embodiments, a shell of two or more different materials is grown on the surface of the core of the quantum dots.

In one of the embodiments, the semiconductor material used for the shell of the quantum dots has a larger band gap than that of the semiconductor material used for the core of the quantum dots.

In one of the embodiments, the shell of the quantum dots and the core of the quantum dots have a I type semiconductor heterojunction structure.

In one of the embodiments, the semiconductor material used for the shell of the quantum dots has a smaller band gap than that used for the core of the quantum dots.

In one of the embodiments, the semiconductor material used for the shell of the quantum dots has an atomic crystal structure that is identical or close to the core of the quantum dots. Such selection is beneficial to reduce the stress between the core and the shell, making the quantum dots more stable.

In one of the embodiments, the core-shell structure of the quantum dots having red light includes one of CdSe/CdS, CdSe/CdS/ZnS, and CdSe/CdZnS.

In one of the embodiments, the core-shell structure of the quantum dots having green light includes one of CdZnSe/CdZnS and CdSe/ZnS.

In one of the embodiments, the core-shell structure of the quantum dots having blue light includes one of CdS/CdZnS and CdZnS/ZnS.

In one of the embodiments, the method of preparing the quantum dots is colloidal growth method.

In one of the embodiments, the method of preparing monodisperse quantum dots is at least one selected from hot-inject and heating-up. The specific preparation method is contained in the documents: Nano Res, 2009, 2, 425-447; Chem. Mater., 2015, 27(7), 2246-2285.

In one of the embodiments, the surface of the quantum dots contains an organic ligand. The organic ligand can control the growth process of the quantum dots, regulate the morphology of the quantum dots and reduce surface defects of the quantum dots, so as to improve the luminous efficiency and stability of the quantum dots.

In one of the embodiments, the organic ligand on the surface of the quantum dots includes at least one selected from the group consisting of pyridine, pyrimidine, furan, amine, alkylphosphine, alkylphosphine oxide, alkylphosphonic acid, alkylphosphinic acid and alkyl mercaptan.

In one of the embodiments, the organic ligand on the surface of the quantum dots includes at least one of tri-n-octylphosphine, tri-n-octylphosphine oxide, trihydroxypropylphosphine, tributylphosphine, tris(dodecyl)phosphine, dibutyl phosphite, tributyl phosphite, octadecyl phosphite, trilauryl phosphite, tris(dodecyl) phosphite, triisodecyl phosphite, bis(2-ethylhexyl) phosphate, tris(tridecyl)phosphate, hexadecylamine, oleylamine, octadecylamine, dioctadecylamine, trioctadecylamine, bis(2-ethylhexyl)amine, octylamine, dioctylamine, trioctylamine, dodecylamine, didodecylamine, tridodecylamine, phenylphosphoric acid, hexylphosphoric acid, tetradecylphosphoric acid, octylphosphoric acid, n-octadecylphosphoric acid, propylene diphosphate, dioctyl ether, diphenyl ether, octyl mercaptan and dodecyl mercaptan.

In one of the embodiments, the surface of the quantum dots contains an inorganic ligand. Quantum dots protected by the inorganic ligand can be obtained by ligand exchange of the organic ligand on the surface of quantum dots.

In one of the embodiments, the inorganic ligand on the surface of the quantum dots includes at least one selected from the group consisting of S²⁻, HS⁻, Se²⁻, HSe⁻, Te^{2-,} HTe⁻, TeS₃²⁻, OH⁻, NH²⁻, PO₄^{3-,} and MoO₄²⁻.

In one of the embodiments, examples of inorganic ligand quantum dots on the surface of quantum dots can be found in J. Am. Chem. Soc. 2011, 133, 10612-10620; ACS Nano, 2014, 9, 9388-9402.

In one of the embodiments, the surface of the quantum dots comprises at least one of the inorganic ligand and the organic ligand.

In one of the embodiments, the luminescence spectrum exhibited by the monodisperse quantum dots has a symmetrical peak shape and a narrow half-peak width. In general, the better the monodispersity of quantum dots is, the more symmetric the luminescence peaks are, and the narrower the half-width is.

In one of the embodiments, the luminescent half-peak width of the quantum dots is less than 70 nanometers.

In one of the embodiments, the luminescent half-peak width of the quantum dots is less than 40 nanometers.

In one of the embodiments, the luminescent half-peak width of the quantum dots is less than 30 nanometers.

In one of the embodiments, the luminescent quantum efficiency of the quantum dots is greater than 10%.

In one of the embodiments, the luminescent quantum efficiency of the quantum dots is greater than 50%.

In one of the embodiments, the luminescent quantum efficiency of the quantum dots is greater than 60%.

In one of the embodiments, the luminescent quantum efficiency of the quantum dots is greater than 70%.

In one of the embodiments, the materials, techniques, methods, and applications of the quantum dots are described in the following patent documents: WO2007/117698, WO2007/120877, WO2008/108798, WO2008/105792, WO2008/111947, WO2007/092606, WO2007/117672, WO2008/033388, WO2008/085210, WO2008/13366, WO2008/063652, WO2008/063653, WO2007/143197, WO2008/070028, WO2008/063653, U.S. Pat. Nos. 6,207,229, 6,251,303, 6,319,426, 6,426,513, 6,576,291, 6,607,829, 6,861,155, 6,921,496, 7,060,243, 7,125,605, 7,138,098, 7,150,910, 7,470,379, 7,566,476, WO2006134599A1.

In one of the embodiments, the quantum dots comprise a luminescent perovskite nanoparticle material. The luminescent perovskite nanoparticle material has the structural general formula of FMG₃, wherein F is an organic amine or an alkali metal, M is a metal, and G is oxygen or halogen.

In one of the embodiments, the luminescent perovskite nanoparticle material includes at least one selected from the group consisting of CsPbCl₃, CsPb(Cl/Br)₃, CsPbBr₃, CsPb(I/Br)₃, CsPbI₃, CH₃NH₃PbCl₃, CH₃NH₃Pb(Cl/Br)₃, CH₃NH₃PbBr₃, CH₃NH₃Pb(I/Br)₃ and CH₃NH₃PbI₃.

In one of the embodiments, the luminescent perovskite nanoparticle material is at least one selected from the following literatures: NanoLett., 2015, 15, 3692-3696; ACS Nano, 2015, 9, 4533-4542; AngewandteChemie, 2015, 127(19): 5785-5788; Nano Lett., 2015, 15(4), 2640-2644; Adv. Optical Mater. 2014, 2, 670-678; J. Phys. Chem. Lett, 2015, 6(3): 446-450; J. Mater. Chem. A, 2015, 3, 9187-9193; Inorg. Chem. 2015, 54, 740-745; RSC Adv., 2014, 4, 55908-55911; J. Am. Chem. Soc., 2014, 136(3), 850-853; Part. Part. Syst. Charact. 2015, 32(7), 709-720 and Nanoscale, 2013, 5(19): 8752-8780.

Quantum dot is a processable semiconductor nanocrystal with dimensionally tunable photoelectronic properties. By changing the size of the quantum dot or changing its composition, the emission wavelength of the quantum dot can be adjusted in all visible bands, meanwhile the half-peak width of luminescence spectrum of the quantum dot is generally less than 30 nm, which can realize a display with high color gamut and white-light illumination with high color rendering index.

The hole transport layer is located between the anode and the light-emitting layer, and includes an organic hole transporting material having a HOMO_{HTM}≤−5.4 eV and □(HOMO−1)_{HTM}−HOMO_{HTM}□≥0.3 eV.

In one of the embodiments, the organic hole transporting material has a HOMO_{HTM}≤−5.5 eV.

In one of the embodiments, the organic hole transporting material has a HOMO_{HTM}≤−5.6 eV.

In one of the embodiments, the organic hole transporting material has a HOMO_{HTM}≤−5.7 eV.

In one of the embodiments, □(HOMO−1)_{HTM}−HOMO_{HTM}□≥0.35 eV.

In one of the embodiments, □(HOMO−1)_{HTM}−HOMO_{HTM}□≥0.4 eV.

In one of the embodiments, □(HOMO−1)_{HTM}−HOMO_{HTM}□≥0.45 eV.

In one of the embodiments, □(HOMO−1)_{HTM}−HOMO_{HTM}□≥00.5 eV.

In one of the embodiments, the organic hole transporting material has a LUMO_{HTM}≥−4.5 eV.

In one of the embodiments, the organic hole transporting material has a LUMO_{HTM}≥−4.2 eV.

In one of the embodiments, the organic hole transporting material has a LUMO_{HTM}≥−3.9 eV.

In one of the embodiments, the organic hole transporting material has a LUMO_{HTM}≥−3.6 eV.

Generally, the valence band energy level of inorganic quantum dots is between −6.0 and −7.0 eV. The organic hole transporting material with deep HOMO energy level is beneficial to reduce the injection barrier between the organic hole transporting material and the quantum dot material, which facilitates the charge transfer balance of the device and improves device efficiency. Meanwhile, an organic hole transporting material having a larger ΔHOMO value (≥0.3 eV) means higher electrooxidation stability, which is advantageous for improving device lifetime.

In one of the embodiments, the organic hole transporting material is at least one selected from the group consisting of a small molecule organic hole transporting material and a hpolymer organic hole transporting material.

In one of the embodiments, the organic hole transporting material includes a small molecule hole transporting material having the following general formula (I):

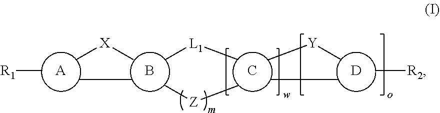

wherein -L₁- is a linking group, and -L₁- is a single bond or an arylene group containing 6 to 30 carbon atoms.

In one of the embodiments, -L₁- is one selected from the group consisting of an aryl group containing 5 to 50 carbon atoms, and a heteroaryl group containing 5 to 50 carbon atoms.

A, B, C, and D are each independently an aromatic ring containing 6 to 40 carbon atoms or a heteroaromatic ring containing 5 to 40 carbon atoms.

In one of the embodiments, A, B, C, and D are each independently selected from the group consisting of an aryl group containing 5 to 30 carbon atoms, and a heteroaryl group containing 5 to 30 carbon atoms.

In one of the embodiments, A, B, C, and D are each independently selected from the group consisting of an aryl group containing 5 to 25 carbon atoms, and a heteroaryl group containing 5 to 25 carbon atoms.

In one of the embodiments, A, B, C, and D are each independently selected from the group consisting of an aryl group containing 5 to 20 carbon atoms, and a heteroaryl group containing 5 to 20 carbon atoms.

—X—, —Y—, and —Z— are each independently selected from the group consisting of —NR₁₁—, —CR₁₂R₁₃—, —O—, and —S—.

In one of the embodiments, at least one of the —X—, —Y—, and —Z— is —NR₁₁—.

In one of the embodiments, at least two of the —X—, —Y—, and —Z— are —NR₁₁—.

In one of the embodiments, all of the —X—, —Y—, and —Z— are —NR₁₁—.

R₁, R₂, R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms.

m, w, and o are each independently 0 or 1.

In one of the embodiments, m is 0, w is 1, and o is 1.

In one of the embodiments, m is 1, w is 1, and o is 0.

In one of the embodiments, the small molecule hole transporting material has a relative molecular mass of ≤3000 g/mol.

In one of the embodiments, the small molecule hole transporting material has a relative molecular mass of ≤2000 g/mol.

In one of the embodiments, the small molecule hole transporting material has a relative molecular mass of ≤1500 g/mol.

In one of the embodiments, the organic hole transporting material is a compound having one of the following general formulas (II)-(IV):

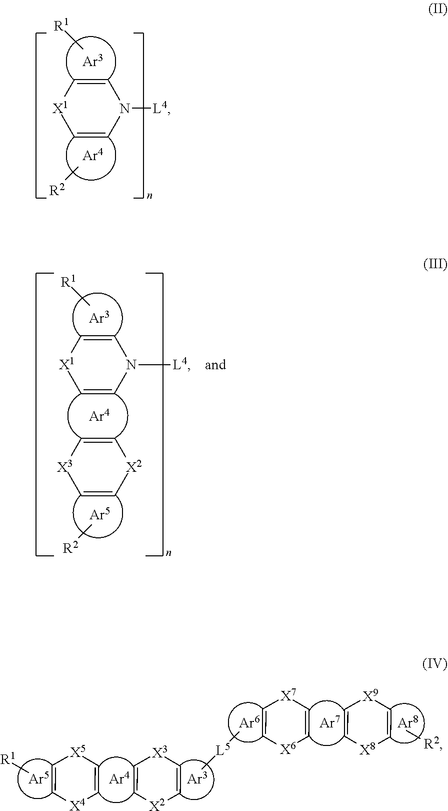

wherein -L⁴- is a linking group, and -L⁴- is an aryl group containing 5 to 60 carbon atoms or a heteroaryl group containing 5 to 60 carbon atoms.

-L⁵- is a linking group, and -L⁵- is one selected from the group consisting of a single bond, an aryl group containing 5 to 30 carbon atoms, and a heteroaryl group containing 5 to 30 carbon atoms; and attachment position of L⁴ may be any carbon atom on the ring.

In one of the embodiments, -L¹- and -L⁵- in the general formulas (I) and (IV) are each a single bond.

In one of the embodiments, -L¹-, -L⁴-, and -L⁵- in the general formulas (I) to (IV) are each independently selected from the group consisting of an aryl group containing 5 to 50 carbon atoms, and a heteroaryl group containing 5 to 50 carbon atoms.

In one of the embodiments, -L¹-, -L⁴-, and -L⁵- in the general formulas (I) to (IV) are each independently selected from the group consisting of an aryl group containing 5 to 40 carbon atoms, and a heteroaryl group containing 5 to 40 carbon atoms.

In one of the embodiments, -L¹-, -L⁴-, and -L⁵- in the general formulas (I) to (IV) are each independently selected from the group consisting of an aryl group containing 5 to 30 carbon atoms, and a heteroaryl group containing 5 to 30 carbon atoms.

In one of the embodiments, -L¹-, -L⁴-, and -L⁵- in the general formulas (I) to (IV) are each independently selected from the group consisting of an aryl group containing 5 to 20 carbon atoms, and a heteroaryl group containing 5 to 20 carbon atoms.

In one of the embodiments, -L¹-, -L⁴-, and -L⁵- in the general formulas (I) to (IV) have one of the following structural groups:

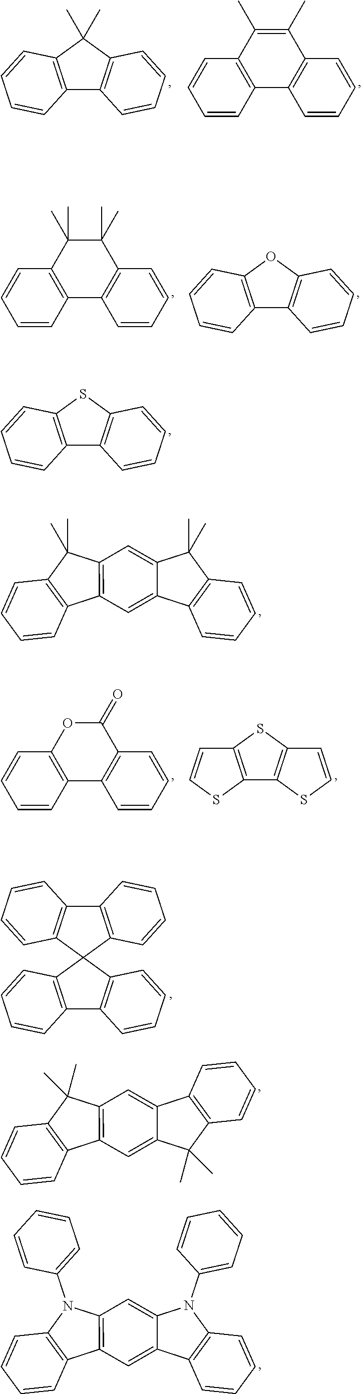

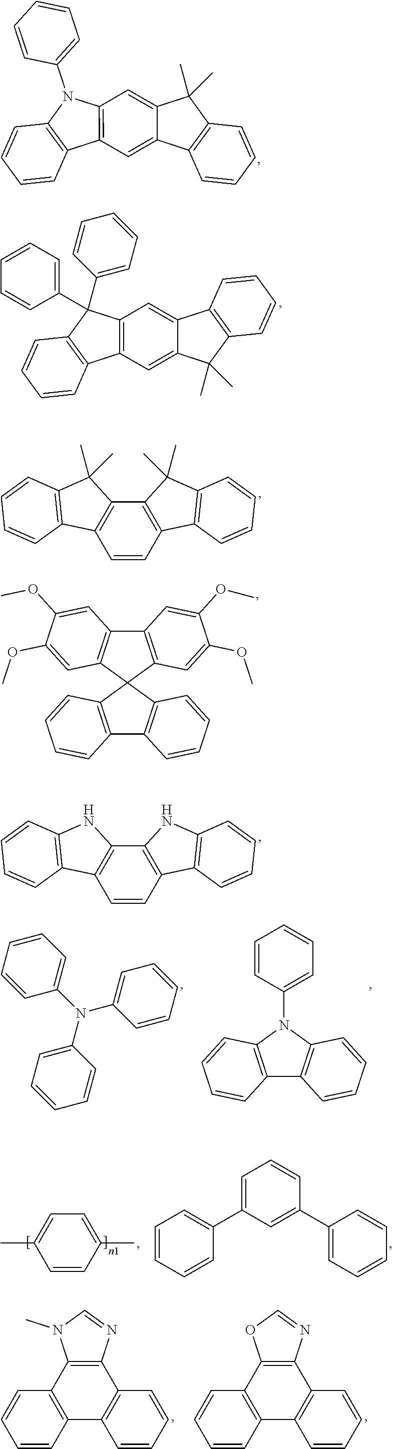

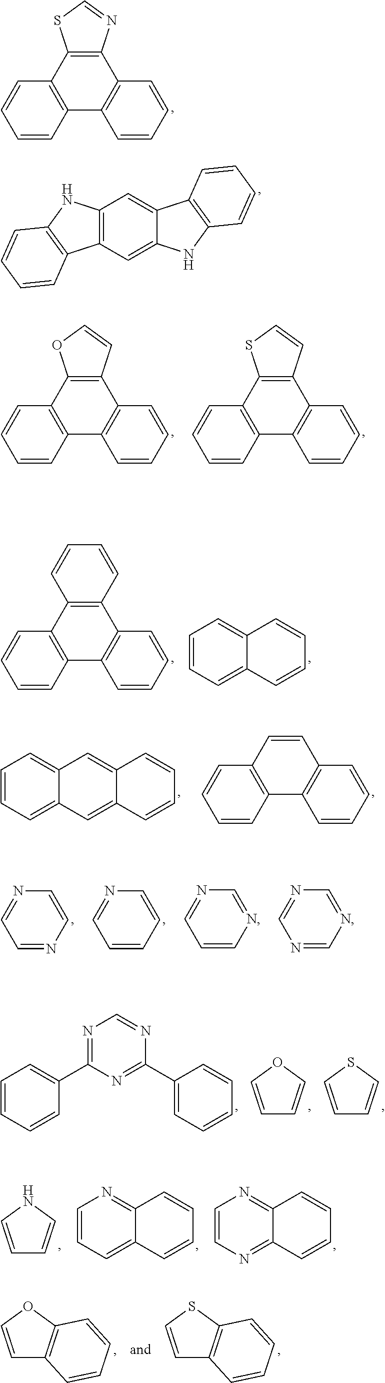

wherein n1 is an integer from 1 to 4.

In one of the embodiments, A, B, C, D, Ar³, Ar⁴, Ar⁵, Ar⁶, Ar⁷, and Ar⁸ are each independently selected from the group consisting of an aryl group containing 5 to 40 carbon atoms, and a heteroaryl group containing 5 to 40 carbon atoms.

In one of the embodiments, A, B, C, D, Ar³, Ar⁴, Ar⁵, Ar⁶, Ar⁷, and Ar⁸ are each independently selected from the group consisting of an aryl group containing 5 to 30 carbon atoms, and a heteroaryl group containing 5 to 30 carbon atoms.

In one of the embodiments, A, B, C, D, Ar³, Ar⁴, Ar⁵, Ar⁶, Ar⁷, and Ar⁸ are each independently selected from the group consisting of an aryl group containing 5 to 25 carbon atoms, and a heteroaryl group containing 5 to 25 carbon atoms.

In one of the embodiments, A, B, C, D, Ar³, Ar⁴, Ar⁵, Ar⁶, Ar⁷, and Ar⁸ are each independently selected from the group consisting of an aryl group containing 5 to 20 carbon atoms, and a heteroaryl group containing 5 to 20 carbon atoms.

The aromatic ring system or aryl group refers to the hydrocarbyl comprising at least one aromatic ring, and including monocyclic group and polycyclic ring system. The heteroaromatic ring system or heteroaryl group refers to the hydrocarbyl comprising at least one heteroaromatic ring (containing heteroatoms), and including monocyclic group and polycyclic ring system. Such polycyclic rings may have two or more rings, and two carbon atoms in the polycyclic ring system are shared by two adjacent rings, i.e., fused ring. At least one ring of such polycyclic rings is aromatic or heteroaromatic. In the present embodiment, the aromatic or heteroaromatic ring system not only includes a system of aryl group or heteroaryl group, but also includes a plurality of aryl groups or a plurality of heteroaryl groups which may also be spaced by short non-aromatic units with the atomic number ratio of less than 10%. In one of the embodiments, a plurality of aryl groups or a plurality of heteroaryl groups is spaced by non-H atoms with the atomic number ratio of less than 5%. The non-H atoms include at least one of C, N, and 0.

In one of the embodiments, the aryl group is selected from one of the following compounds: 9,9′-spirobifluorene, and 9,9-diarylfluorene.

In one of the embodiments, the heteroaryl group is selected from one of the following compounds: triarylamine, and diaryl ether.

In one of the embodiments, the aryl group is one selected from the group consisting of benzene, derivatives of benzene, naphthalene, derivatives of naphthalene, anthracene, derivatives of anthracene, phenanthrene, derivatives of phenanthrene, perylene, derivatives of perylene, tetracene, derivatives of tetracene, pyrene, derivatives of pyrene, benzopyrene, derivatives of benzopyrene, triphenylene, derivatives of triphenylene, acenaphthene, derivatives of acenaphthene, fluorene, and derivatives of fluorene.

In one of the embodiments, the heteroaryl group is one selected from the group consisting of furan, derivatives of furan, benzofuran, derivatives of benzofuran, thiophene, derivatives of thiophene, benzothiophene, derivatives of benzothiophene, pyrrole, derivatives of pyrrole, pyrazole, derivatives of pyrazole, triazole, derivatives of triazole, imidazole, derivatives of imidazole, oxazole, derivatives of oxazole, oxadiazole, derivatives of oxadiazole, thiazole, derivatives of thiazole, tetrazole, derivatives of tetrazole, indole, derivatives of indole, carbazole, derivatives of carbazole, pyrroloimidazole, derivatives of pyrroloimidazole, pyrrolopyrrole, derivatives of pyrrolopyrrole, thienopyrrole, derivatives of thienopyrrole, thienothiophene, derivatives of thienothiophene, furopyrrole, derivatives of furopyrrole, furofuran, derivatives of furofuran, thienofuran, derivatives of thienofuran, benzisoxazole, derivatives of benzisoxazole, benzisothiazole, derivatives of benzisothiazole, benzimidazole, derivatives of benzimidazole, pyridine, derivatives of pyridine, pyrazine, derivatives of pyrazine, pyridazine, derivatives of pyridazine, pyrimidine, derivatives of pyrimidine, triazine, derivatives of triazine, quinoline, derivatives of quinoline, isoquinoline, derivatives of isoquinoline, cinnoline, derivatives of cinnoline, quinoxaline, derivatives of quinoxaline, phenanthridine, derivatives of phenanthridine, perimidine, derivatives of perimidine, quinazoline, derivatives of quinazoline, quinazolinone and derivatives of quinazolinone.

In one of the embodiments, A, B, C, D, Ar³, Ar⁴, Ar⁵, Ar⁶, Ar⁷, and Ar⁸ include one of the following structural groups:

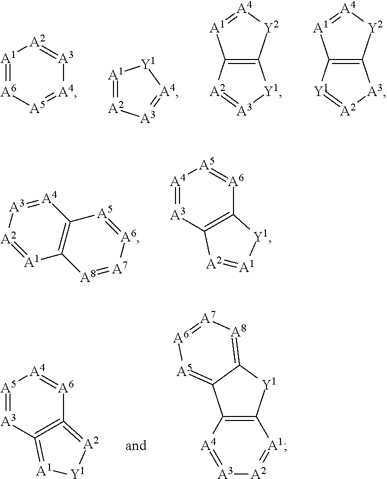

wherein A¹, A², A³, A⁴, A⁵, A⁶, A⁷, and A⁸ are each independently selected from CR³ and N.

Y¹, Y² are each independently selected from the group consisting of CR⁴R⁵, SiR⁴R⁵, NR³, C(═O), S, and O.

R³, R⁴, and R⁵ are each selected from of the group consisting of H, D, a linear alkyl group containing 1 to 20 carbon atoms, an alkoxy group containing 1 to 20 carbon atoms, a thioalkoxy group containing 1 to 20 carbon atoms, a branched alkyl group containing 3 to 20 carbon atoms, a cyclic alkyl group containing 3 to 20 carbon atoms, a silyl group containing 3 to 20 carbon atoms, a carbonyl group containing 1 to 20 carbon atoms, an alkoxycarbonyl group containing 2 to 20 carbon atoms, an aryloxycarbonyl group containing 7 to 20 C atoms, a cyano group (—CN), a carbamoyl group (—C(═O)NH₂), a halocarbonyl group (C(═O)—X, wherein X represents a halogen atom), a formyl group (—C(═O)—H), an isocyano group, an isocyanate group, a thiocyanate group, an isothiocyanate group, hydroxyl group, nitro group, a CF₃ group, Cl, Br, F, a crosslinkable group, an aryl group containing 5 to 40 carbon atoms, a heteroaromatic ring system containing 5 to 40 carbon atoms, an aryloxy containing 5 to 40 carbon atoms and a heteroaryloxy containing 5 to 40 carbon atoms. Wherein one or more groups of the R³, R⁴ and R⁵ can form a monocyclic or polycyclic aliphatic or aromatic ring with each other and/or with a ring bonded to the group.

In one of the embodiments, A, B, C, D, Ar³, Ar⁴, Ar⁵, Ar⁶, Ar⁷, and Ar⁸ include one of the following structural groups:

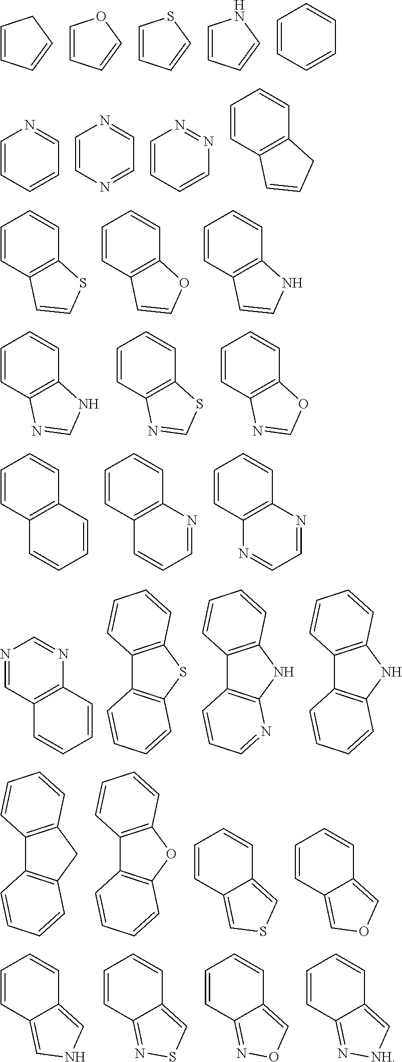

In other embodiments, H on the rings of the above structural groups may be substituted.

—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—,

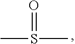

### and —SO₂—;

In one of the embodiments, —X¹— is one selected from the group consisting of a single bond, N(R), C(R)₂, O, and S.

—X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—,

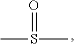

and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously; and in the general formula (IV), at least one of the —X²—, —X³—, —X⁴—, —X⁵—, —X⁶—, —X⁷—, —X⁸—, and —X⁹— is —N(R)—.

In one of the embodiments, —X²—, —X³—, —X⁴—, —X⁵—, —X⁶—, —X⁷—, —X⁸—, and —X⁹— are each independently selected from the group consisting of a signal bond, —N(R)—, —C(R)₂—, —O—, and —S—.

R¹, R², and R are each independently represent the group consisting of H, D, F, CN, alkenyl, alkynyl, nitrile, amine, nitro, acyl, alkoxy, carbonyl, sulfonyl, and an alkyl group containing 1 to 30 carbon atoms, a cycloalkyl group containing 3 to 30 carbon atoms, an aromatic hydrocarbyl group containing 6 to 60 carbon atoms, and an aromatic heterocyclyl group containing 5 to 60 carbon atoms; wherein attachment positions of R¹ and R² are carbon atoms on the fused ring. The attachment positions of R¹ and R² may be on any carbon atoms on the fused ring. And there may be a plurality of carbon atoms substituted by R¹ and R².

In one of the embodiments, the carbon atoms on the fused ring of the general formulas (II) to (IV) may be multisubstituted by R¹ and/or R².

n represents an integer from 1 to 4.

In one of the embodiments, n is an integer from 1 to 3.

In one of the embodiments, n is an integer from 1 to 2.

In one of the embodiments, the organic hole transporting material has one of the general formulas (I-1) to (1-9):

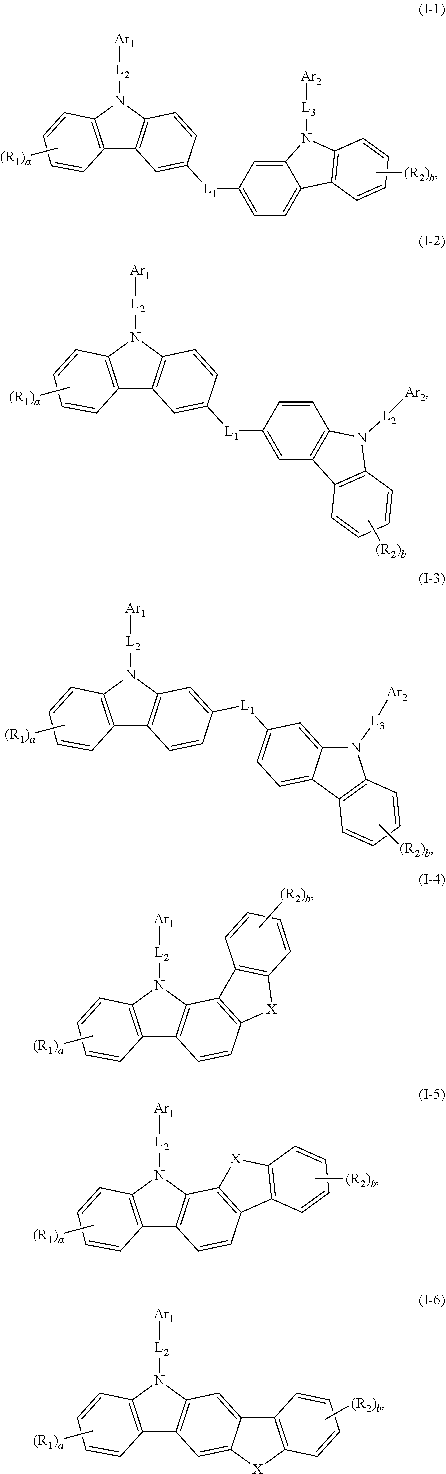

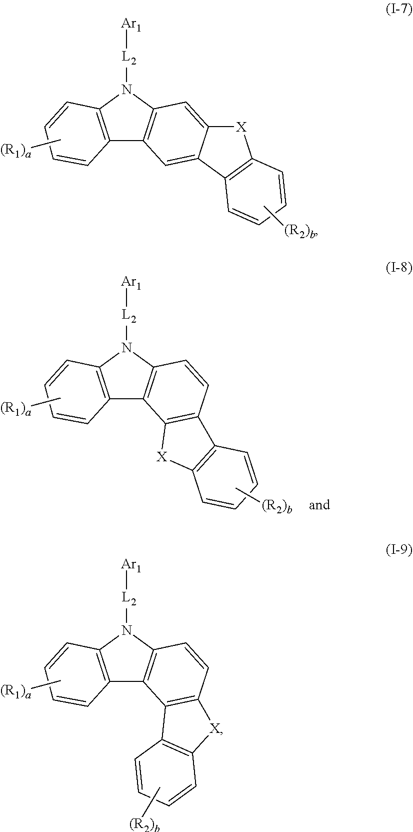

wherein -L²- and -L³ are each independently a single bond or an arylene group containing 6 to 40 carbon atoms;

a and b are each independently an integer of 0 to 4.

Ar₁ and Ar₂ are each independently selected from the group consisting of an aryl group and a heteroaryl group.

In one of the embodiments, Ar₁ and Ar₂ are each independently selected from the group consisting of an aryl group containing 5 to 50 carbon atoms, and a heteroaryl group containing 5 to 50 carbon atoms.

In one of the embodiments, Ar₁ and Ar₂ are each independently selected from the group consisting of an aryl group containing 5 to 40 carbon atoms, and a heteroaryl group containing 5 to 40 carbon atoms.

In one of the embodiments, Ar₁ and Ar₂ are each independently selected from the group consisting of an aryl group containing 6 to 30 carbon atoms, and a heteroaryl group containing 6 to 30 carbon atoms.

In one of the embodiments, the organic hole transporting material of the general formula (II) has one of the following structural formulas:

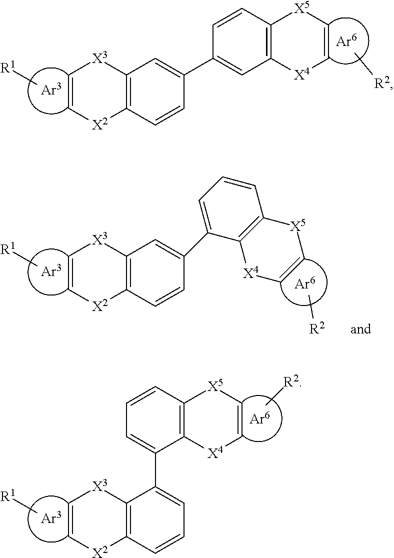

In one of the embodiments, the organic hole transporting material of the general formula (II) has one of the following structural formulas:

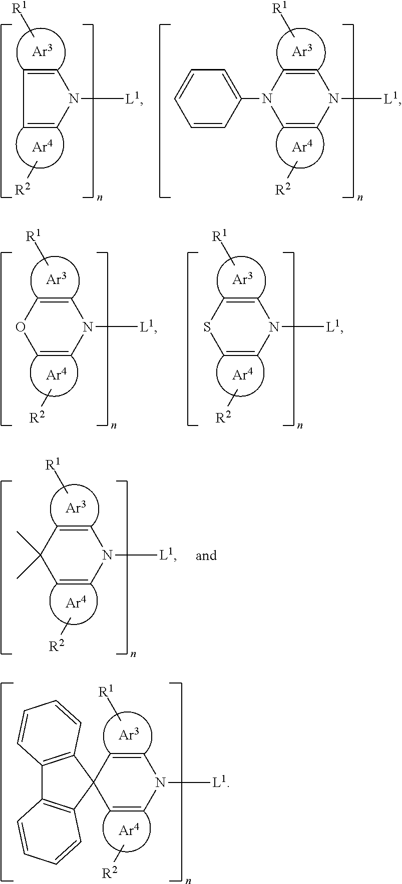

In one of the embodiments, the organic hole transporting material of the general formula (III) has one of the following structural formulas:

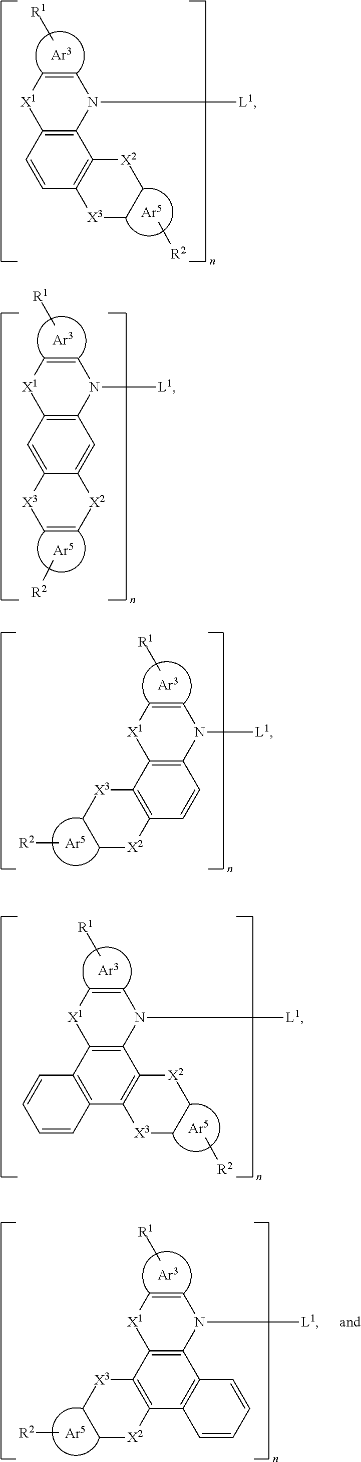

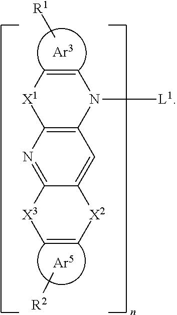

In one of the embodiments, the organic hole transporting material of the general formula (IV) has one of the following structural formulas:

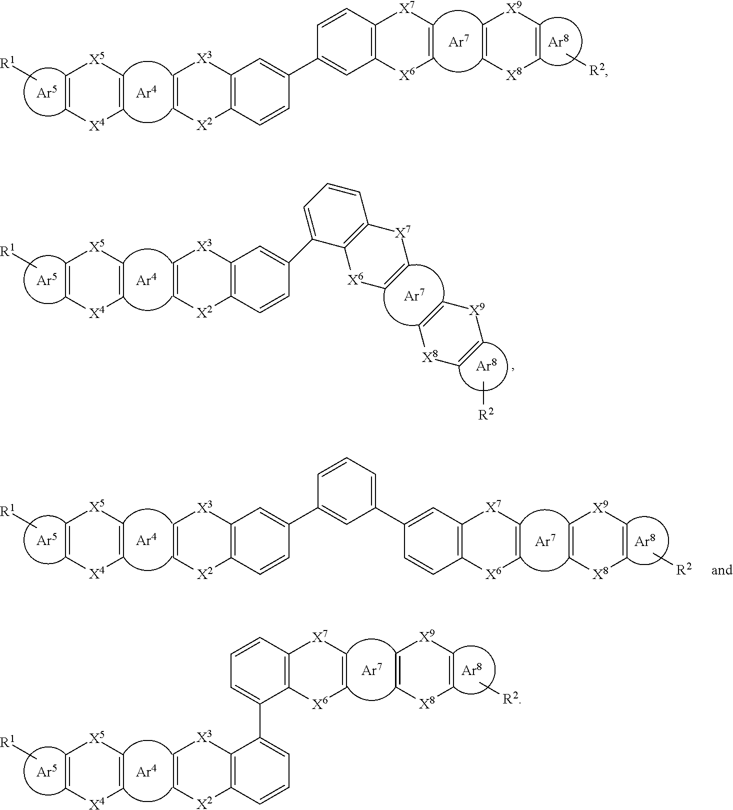

In one of the embodiments, the organic hole transporting material has one of the following structural formulas:

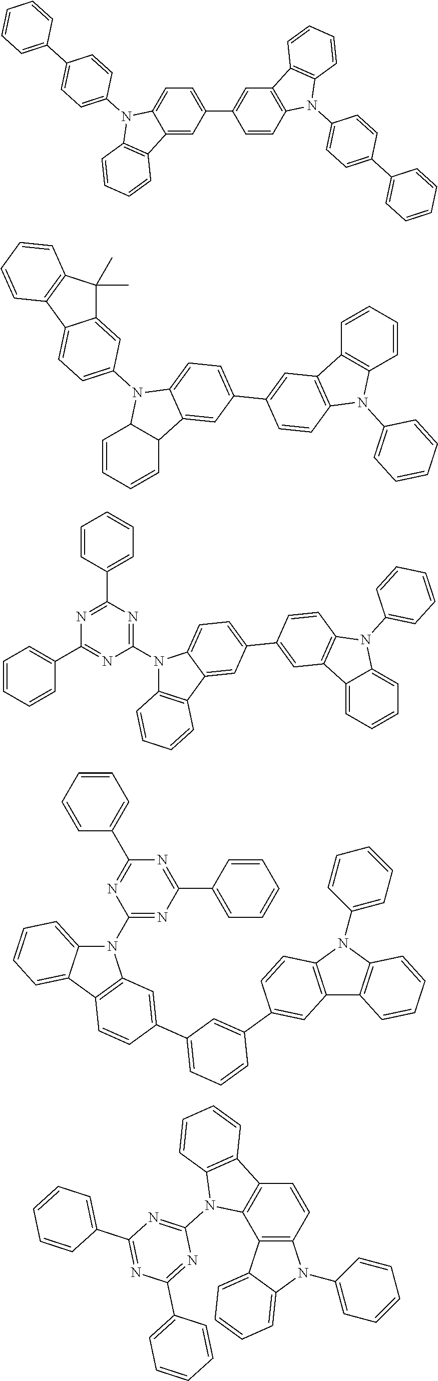

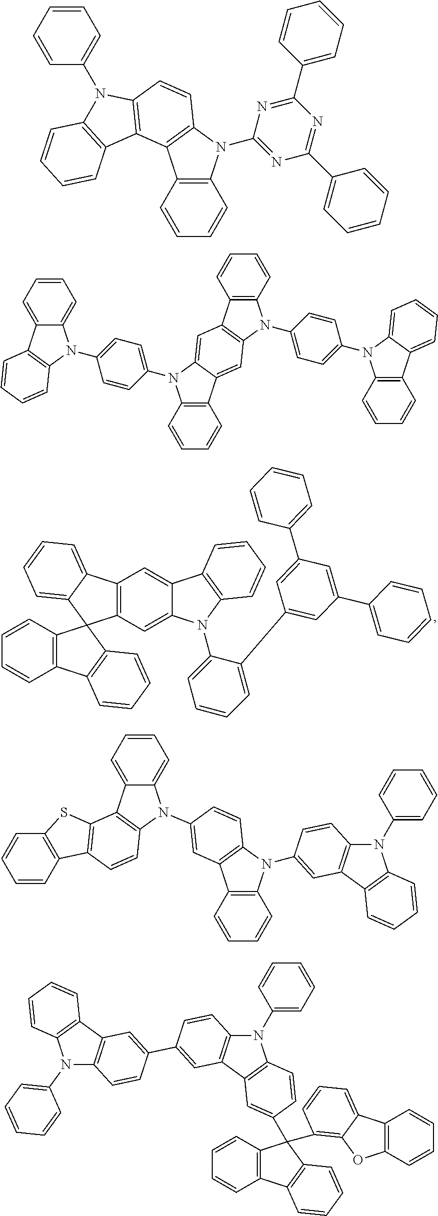

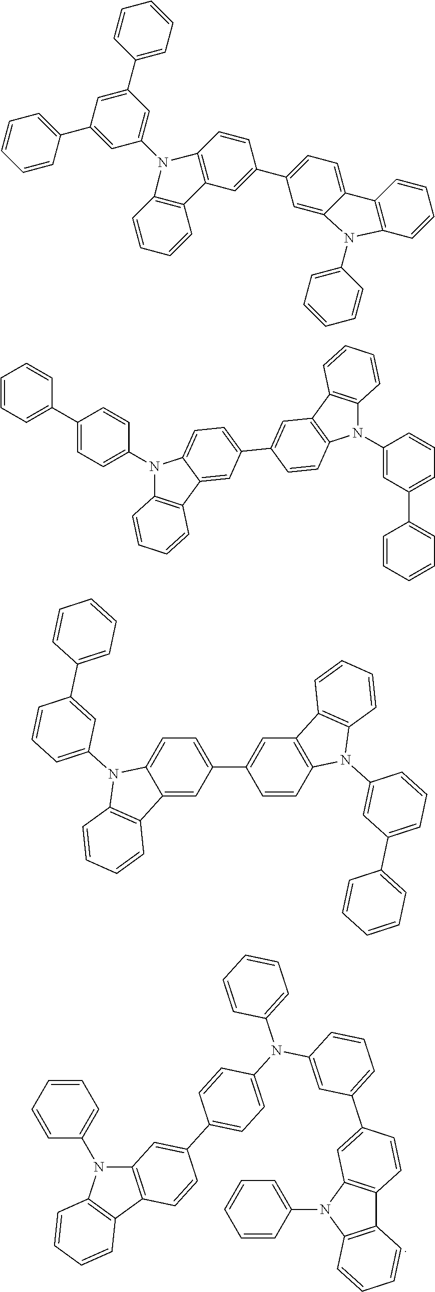

In one of the embodiments, the organic hole transporting material has one of the following structural formulas:

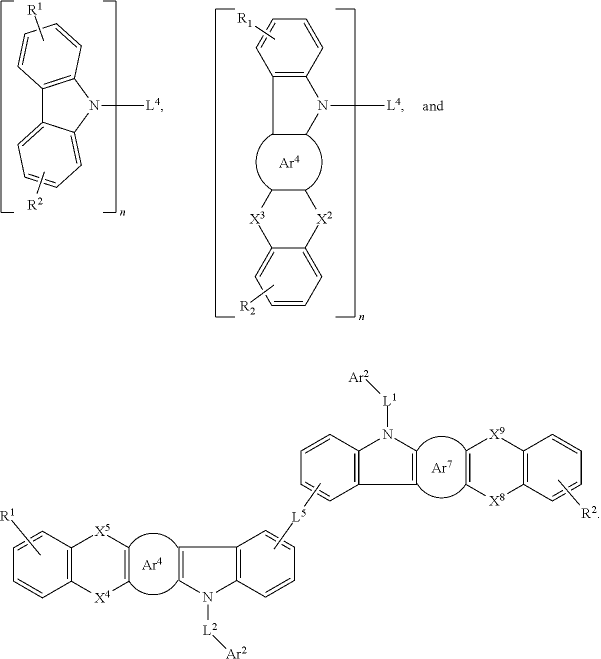

In one of the embodiments, the organic hole transporting material is one selected from compounds having the following general formulas (V) to (VI):

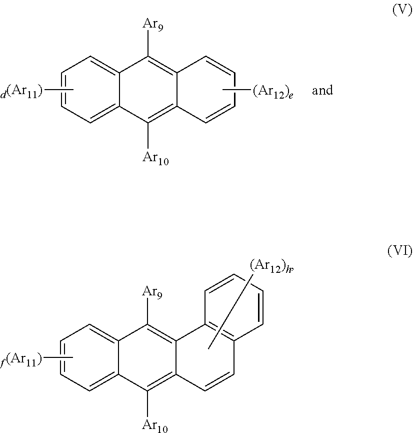

wherein Ar⁹ and Ar¹⁰ are each independently selected from the group consisting of an aryl group containing 6 to 60 carbon atoms, a heteroaryl group containing 3 to 60 carbon atoms, a fused ring aryl group containing 6 to 60 carbon atoms, and a fused ring heteroaryl group containing 3 to 60 carbon atoms.

Ar¹¹ to Ar¹² are each independently selected from the group consisting of H, D, F, —CN, —NO₂, —CF₃, alkenyl, alkynyl, amino, acyl, amide, cyano, isocyano, alkoxy, hydroxy, carbonyl, sulfonyl, an alkyl group containing 1 to 60 carbon atoms, a cycloalkyl group containing 3 to 60 carbon atoms, an aryl group containing 6 to 60 carbon atoms, a heterocyclic aryl group containing 3 to 60 carbon atoms, and a fused ring aryl group containing 7 to 60 carbon atoms, and a fused heterocyclic aryl group containing 4 to 60 carbon atoms; or one or more groups of the groups described above can form a monocyclic or polycyclic aliphatic or aromatic ring with each other or with a ring bonded to the groups.

d, e, and f are each independently an integer from 0 to 4, and h is an integer from 0 to 6.

In one of the embodiments, the organic hole transporting material is one selected from compounds having general formulas (V-1) and (V-2):

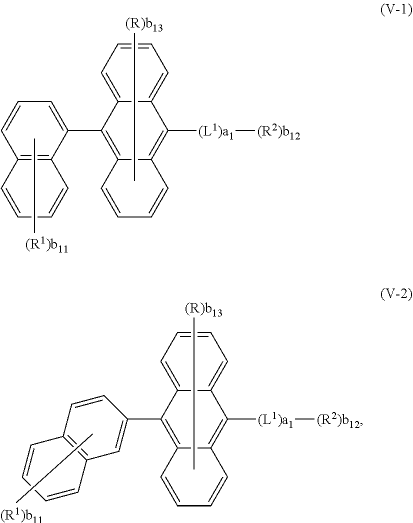

a₁ is integers from 1 to 3. b₁₁, b₁₂, and b₁₃ can be each independently selected from 0, 1, 2, 3, 4, 5 and 6.

In one of the embodiments, the hole transporting material is one selected from compounds having general formulas (V-1a) and (V-2a):

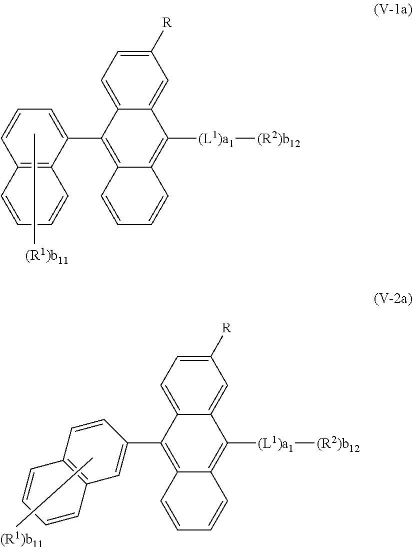

In one of the embodiments, the organic hole transporting material is one selected from the following structural formulas:

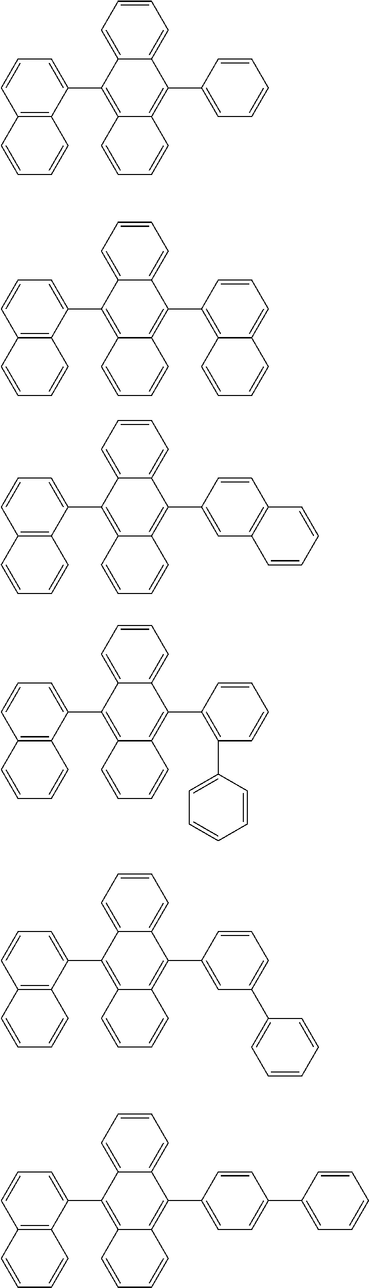

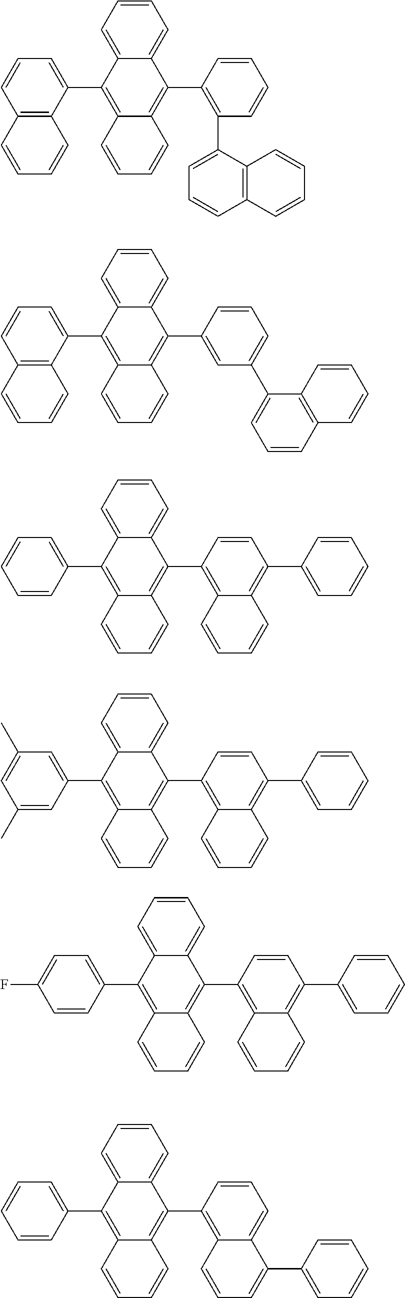

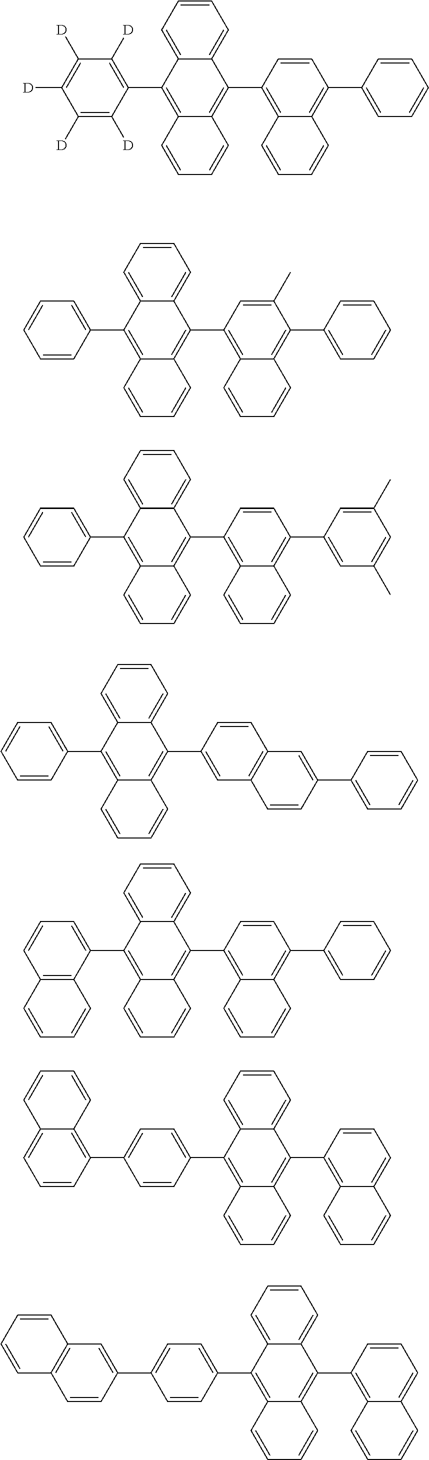

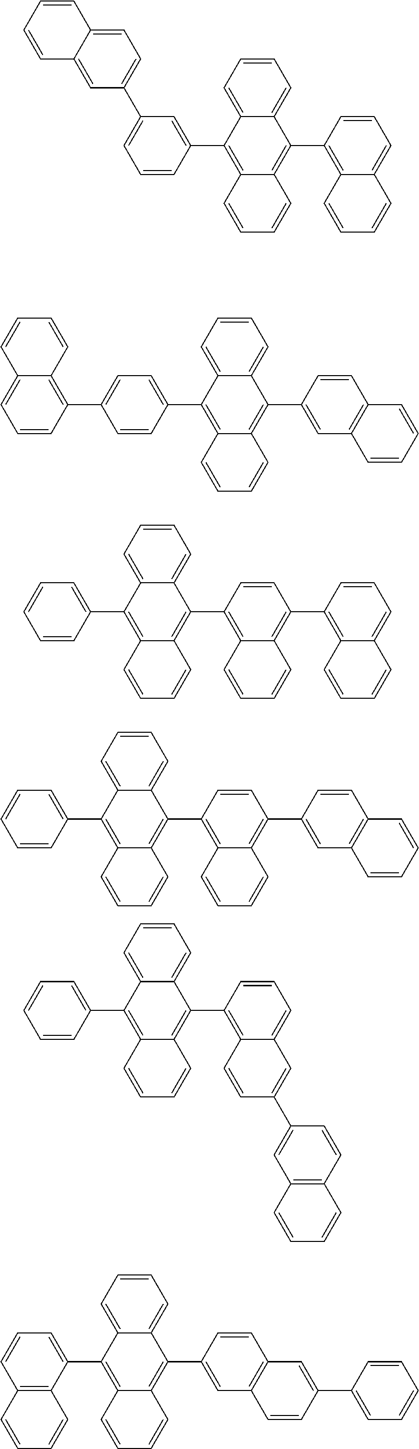

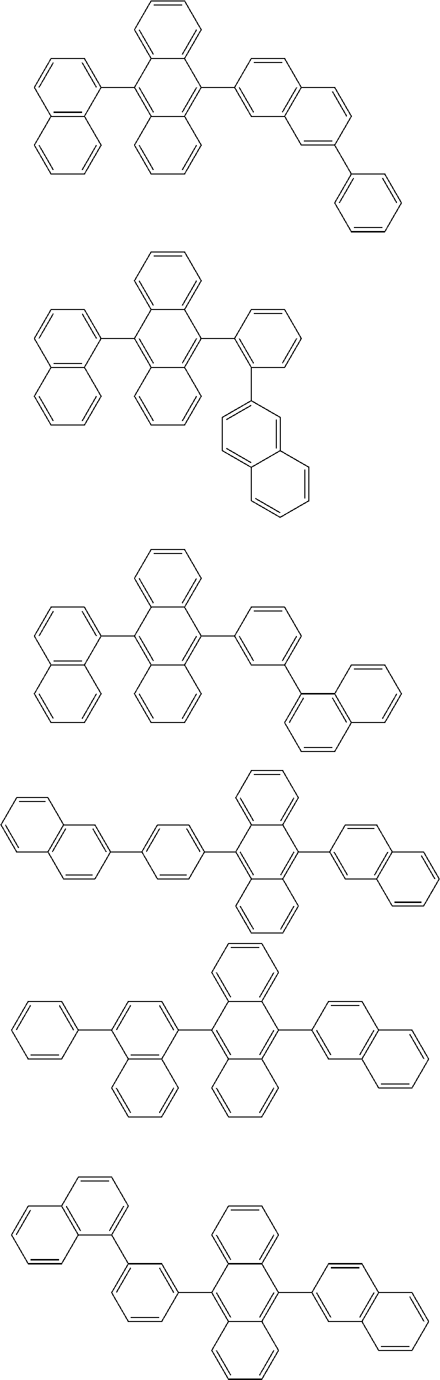

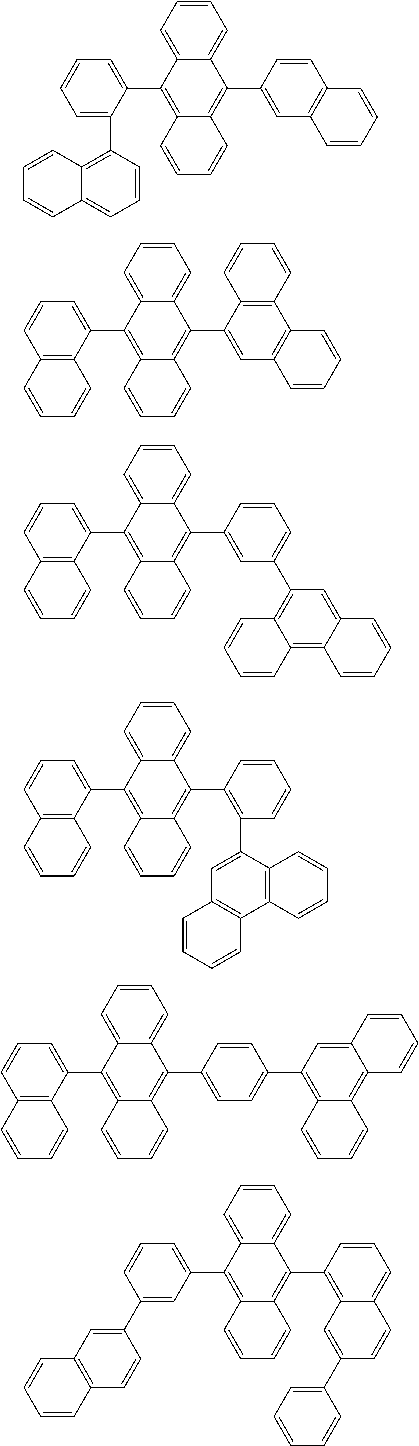

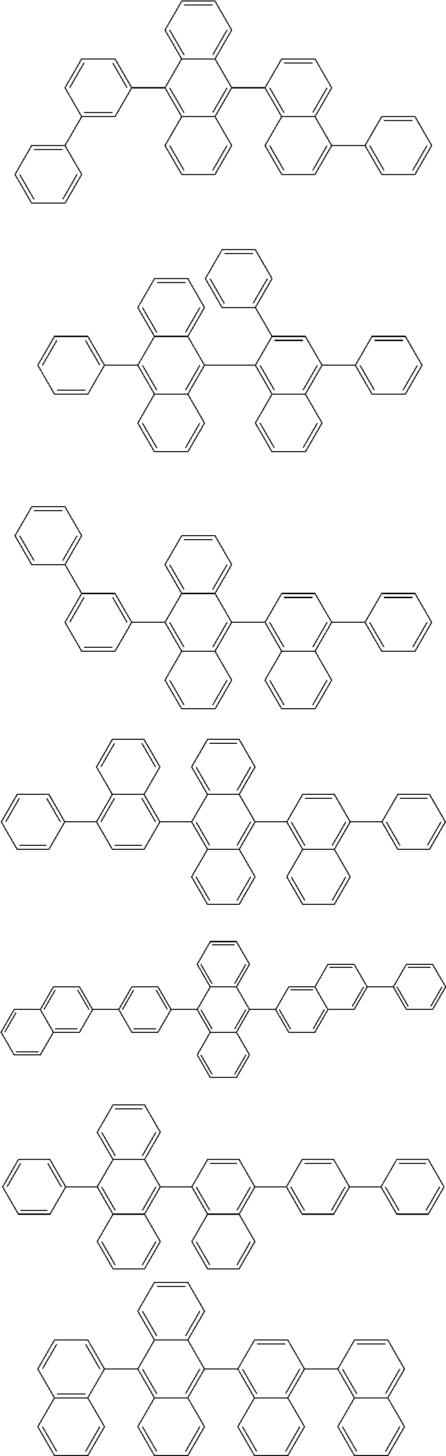

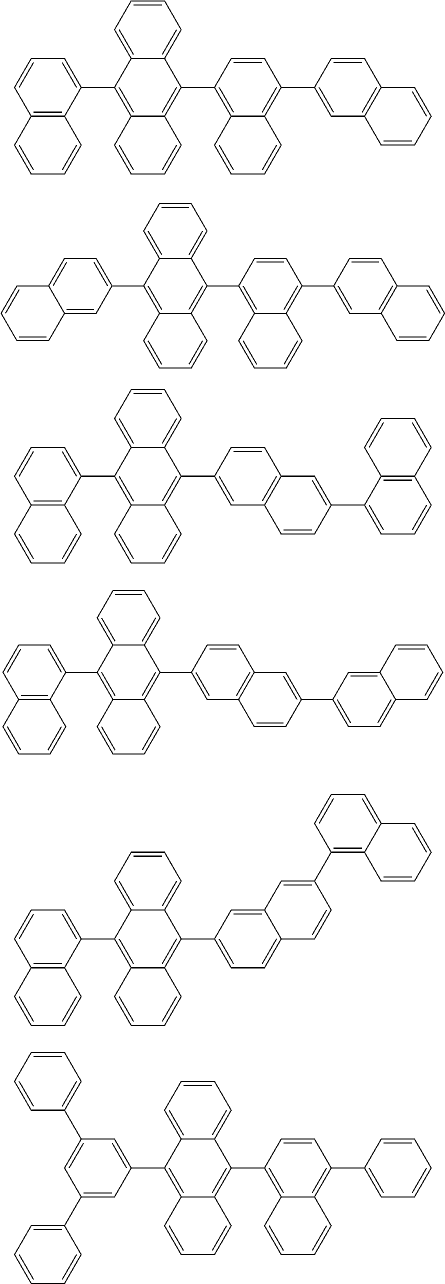

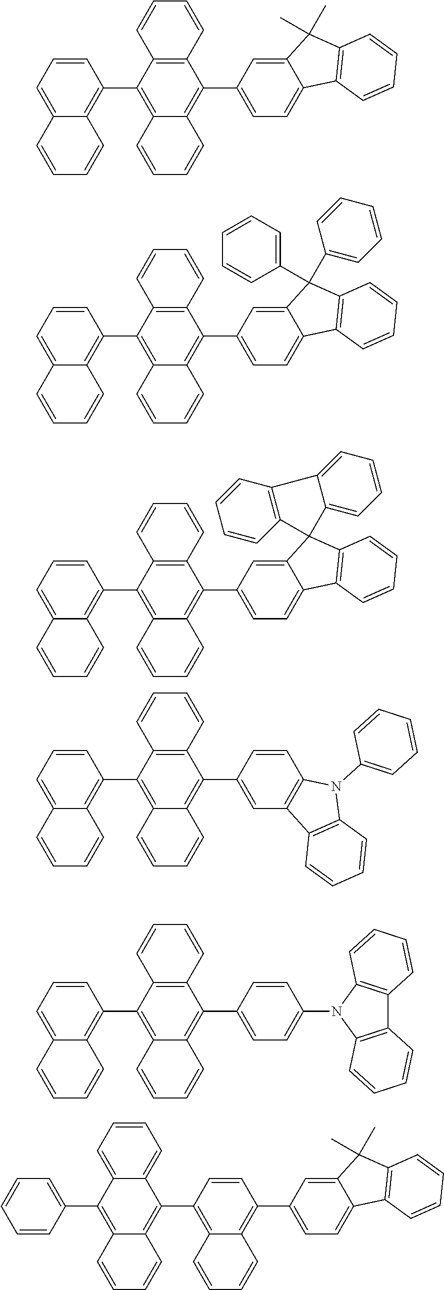

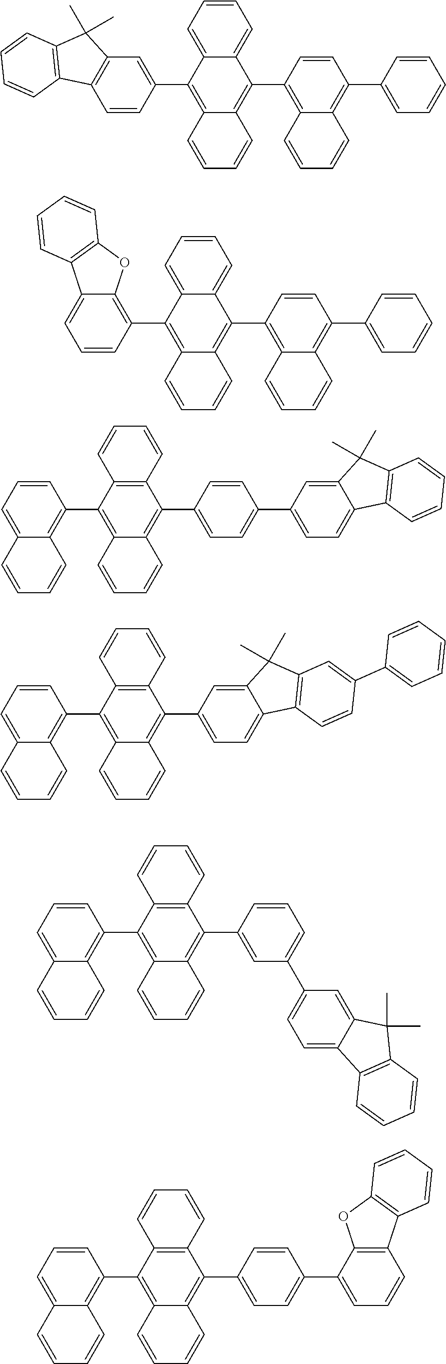

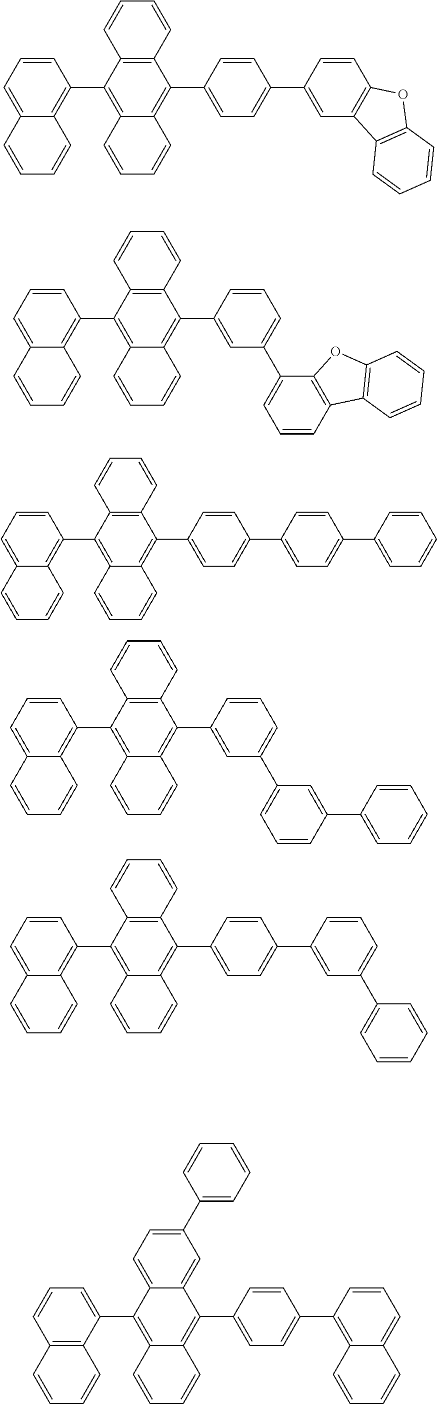

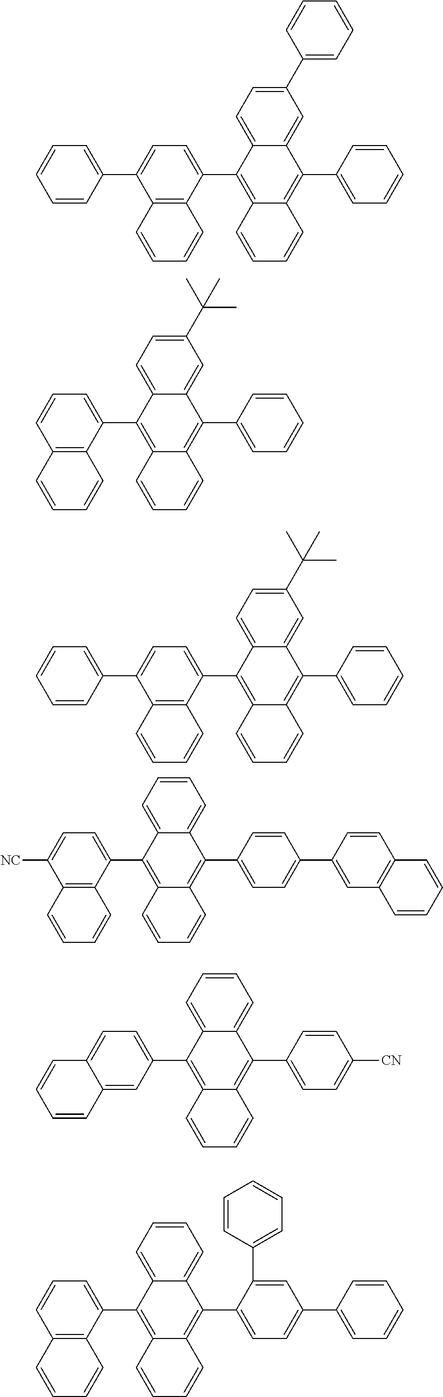

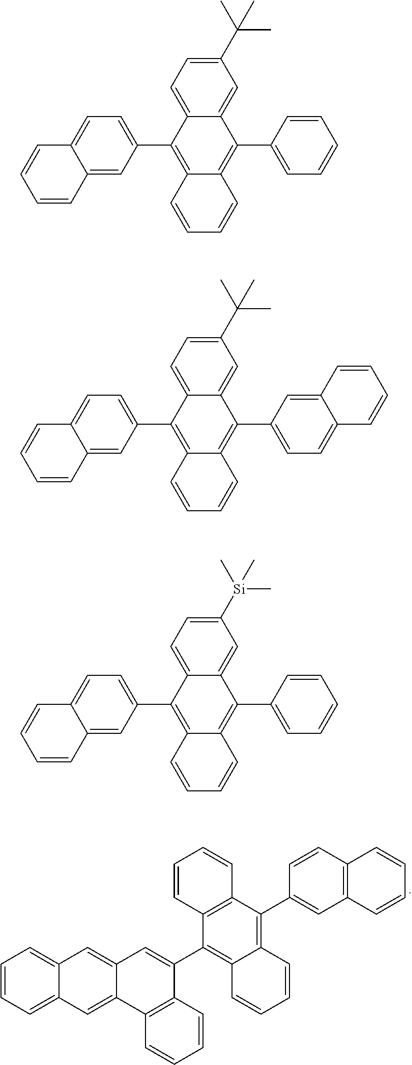

In one of the embodiments, the organic hole transporting material includes a polymer having a highest occupied molecular orbital energy level HOMOp, and a second highest occupied molecular orbital energy level (HOMO−1)p, and HOMOp≤−5.4 eV and □(HOMO−1)p−HOMOp □≥0.3 eV.

In one of the embodiments, the polymer used as the organic hole transporting material is a conjugated polymer, and the repeating constitutional unit thereof includes at least one of the constitutional units represented by general formulas (I) to (VI).

In one of the embodiments, the polymer hole transporting material has at least one of the following general formula (P-1) and general formula (P-2):

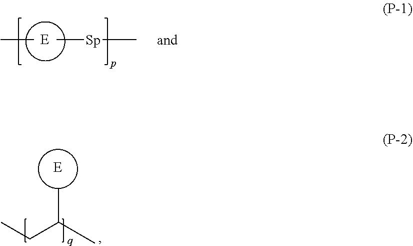

wherein p and q represent the number of repeating units, and both p and q are integers of ≥1;

E is a functional group with hole transporting properties, the highest occupied molecular orbital energy level of high polymer of E is HOMO_{E}, and the second highest occupied molecular orbital energy level is (HOMO−1)_{E}, and HOMO_{E}≤−5.4 eV and □(HOMO−1)_{E}−HOMO_{E}□≥0.3 eV.

In one of the embodiments, E in the polymer may be a group formed by a known material that can be used as the organic hole transporting material.

In one embodiment, the E in the polymer is one selected from the group consisting of amine, derivatives of amine, biphenyl triarylamine, thiophene, thiophthene, pyrrole, aniline, carbazole, indocarbazole, indolocarbazole, pentacene, phthalocyanine, amino porphyrin, derivatives of biphenyl triarylamine, derivatives of thiophene, derivatives of thiophthene, derivatives of pyrrole, derivatives of aniline, derivatives of carbazole, derivatives of indocarbazole, derivatives of indolocarbazole, derivatives of pentacene, derivatives of phthalocyanine, and derivatives of porphyrin.

In one of the embodiments, the repeating constitutional unit of E includes one of the general formulas (I) to (VI).

In one of the embodiments, E is one selected from following structures:

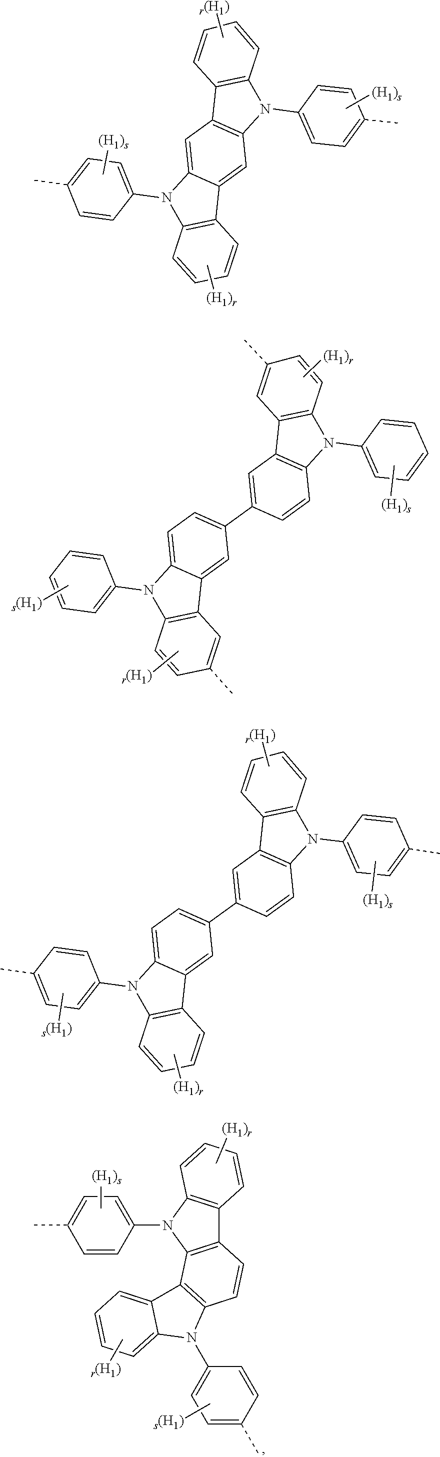

wherein, [symbol] represents a bond bonded to the group.

H₁ is at least one selected from of the group consisting of H, D, a linear alkyl group containing 1 to 20 carbon atoms, an alkoxy group containing 1 to 20 carbon atoms, a thioalkoxy group containing 1 to 20 carbon atoms, a branched alkyl group containing 3 to 20 carbon atoms, a cyclic alkyl group containing 3 to 20 carbon atoms, an alkoxy group containing 3 to 20 carbon atoms, a thioalkoxy group containing 3 to 20 carbon atoms, a silyl group containing 3 to 20 carbon atoms, a carbonyl group containing 1 to 20 carbon atoms, an alkoxycarbonyl group containing 2 to 20 carbon atoms, an aryloxycarbonyl group containing 7 to 20 C atoms, a cyano group (—CN), a carbamoyl group (—C(═O)NH₂), a halocarbonyl group (C(═O)—X, wherein X represents a halogen atom), a formyl group (—C(═O)—H), an isocyano group, an isocyanate group, a thiocyanate group, an isothiocyanate group, hydroxyl group, nitro group, a CF₃ group, Cl, Br, F, a crosslinkable group, an aryl group containing 5 to 40 carbon atoms, a heteroaromatic ring system containing 5 to 40 carbon atoms, an aryloxy containing 5 to 40 carbon atoms and a heteroaryloxy containing 5 to 40 carbon atoms. Wherein one or more groups of the R³, R⁴, and R⁵ can form a monocyclic or polycyclic aliphatic or aromatic ring with each other and/or with a ring bonded to the group.

r is 0, 1, 2, 3, or 4.

s is 0, 1, 2, 3, 4, or 5.

Sp represents a non-conjugated spacer unit. Specifically, it refers to a constitutional unit whose conjugated chain is spaced, such as spaced by at least one sp3-hybridized C atom. Similarly, the conjugated chain can also be spaced by a non-sp3-hybridized atom, such as O, S or Si.

In one of the embodiments, the non-conjugated spacer unit Sp is one selected from the group consisting of a linear alkyl chain containing 1 to 20 carbon atoms and a branched alkyl chain containing 1 to 20 carbon atoms, wherein the non-adjacent C atoms of the chain may be substituted by O, S, NR₁₁, CR₁₂R₁₃, C(═O) or COO.

R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms.

In one of the embodiments, the non-conjugated spacer unit Sp may optionally include a single non-conjugated atom between two conjugated groups, and the non-conjugated spacer unit Sp may optionally include an unconjugated chain containing multiple atoms separating two conjugated groups.

In one of the embodiments, the non-conjugated spacer unit Sp is a linear alkyl group containing 1 to 20 carbon atoms or a branched alkyl group containing 1 to 20 carbon atoms, wherein non-adjacent C atoms of the linear alkyl chain containing 1 to 20 carbon atoms or the branched alkyl chain containing 1 to 20 carbon atoms may be substituted by O, S, NR₁₁, CR₁₂R₁₃, C(═O) or COO.

In one of the embodiments, the non-conjugated spacer unit Sp includes at least one sp3-hybridized carbon atom to separate the two conjugated groups.

In one of the embodiments, the non-conjugated spacer unit Sp is an alkyl chain containing 1 to 20 carbon atoms whose non-adjacent C atoms is substituted by O. A low polyether chain can be provided, such as the formula —O(CH₂CH₂O)ₖ—, wherein k is 1 to 5.

In one of the embodiments, the non-conjugated spacer unit Sp is one selected from the following structures:

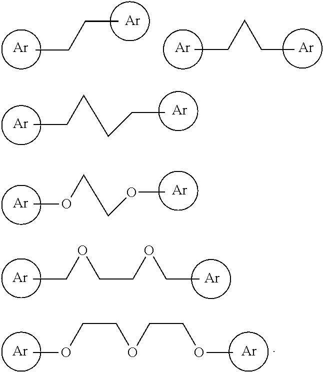

In one of the embodiments, the non-conjugated spacer unit Sp is selected from the group consisting of a linear alkylene, a branched alkylene, cycloalkylene, alkylsilylene, silylene, arylsilylene, alkylalkoxyalkylene, arylalkoxyalkylene, alkylthioalkylene, sulfone, alkylene sulfone, sulfone oxide, alkylene sulfone oxide, wherein the above alkylene group contains 1 to 12 C atoms. In one of the embodiments, the H atom of the above alkylene group may be substituted by F, Cl, Br, I, alkyl, heteroalkyl, cycloalkyl, aryl or heteroaryl.

In one of the embodiments, the non-conjugated spacer unit Sp is one selected from a linear alkylene group containing 1 to 12 C atoms, a linear alkylene group containing 1 to 12 C atoms in which H atoms may be substituted by F, a bifurcated alkylene group containing 1 to 12 C atoms, a bifurcated alkylene group containing 1 to 12 C atoms in which H atoms may be substituted by F, an alkoxyalkylene group containing 1 to 12 C atoms in which H atoms may be substituted by F, and an alkoxyalkylene group containing 1 to 12 C atoms.

In one of the embodiments, the non-conjugated spacer unit Sp is one selected from the following structures:

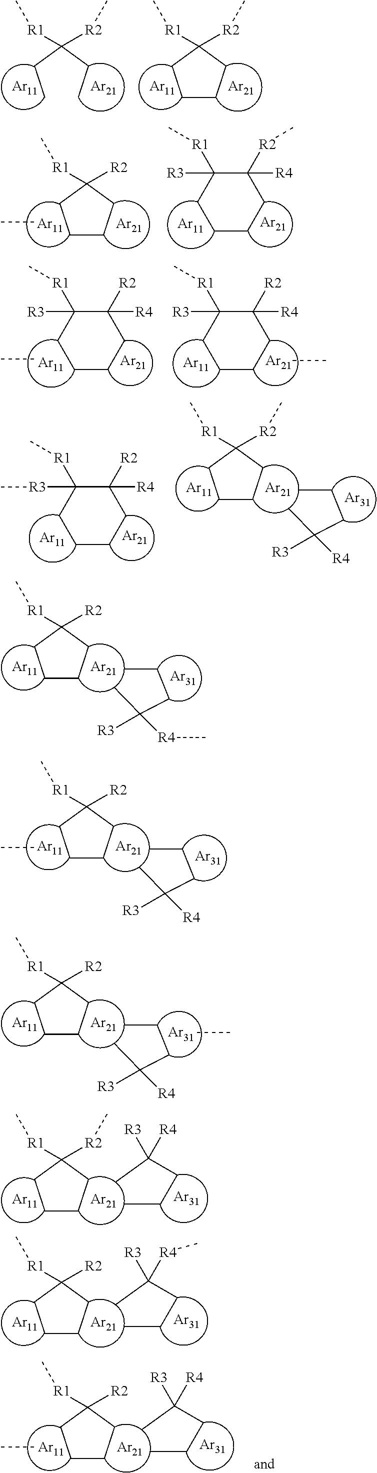

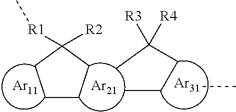

Wherein, Ar₁₁, Ar₂₁, and Ar₃₁ are each independently an aromatic containing 5 to 60 ring atoms or a heteroaromatic containing 5 to 60 ring atoms.

R1, R2, R3, and R4 are each independently selected from the group consisting of alkylene, cycloalkylene, alkylsilylene, silylene, arylsilylene, alkylalkoxyalkylene, arylalkoxyalkylene, alkylthioalkylene, phosphino, phosphine oxide, sulfonyl, alkylenesulfonyl, sulfoneoxy, alkylenesulfoneoxy, wherein the above alkylene contains 1 to 12 C atoms. In other embodiments, the H atom in the above alkylene is substituted by F, Cl, Br, I, alkyl, heteroalkyl, cycloalkyl, aryl or heteroaryl.

Dash line represents bond bonded to the group.

In one of the embodiments, R1, R2, R3, and R4 are on an atom attached to Ar₁, Ar₂, and Ar₃.

In one of the embodiments, R1, R2, R3, and R4 are on two adjacent atoms connected between Ar₁, Ar₂, and Ar₃.

In one of the embodiments, the atoms attached to R1, R2, R3, and R4 are atoms on the aromatic ring.

In one of the embodiments, the atoms attached to R1, R2, R3, and R4 are heterocyclic atoms.

In one of the embodiments, the non-conjugated spacer unit Sp has one of the following structures:

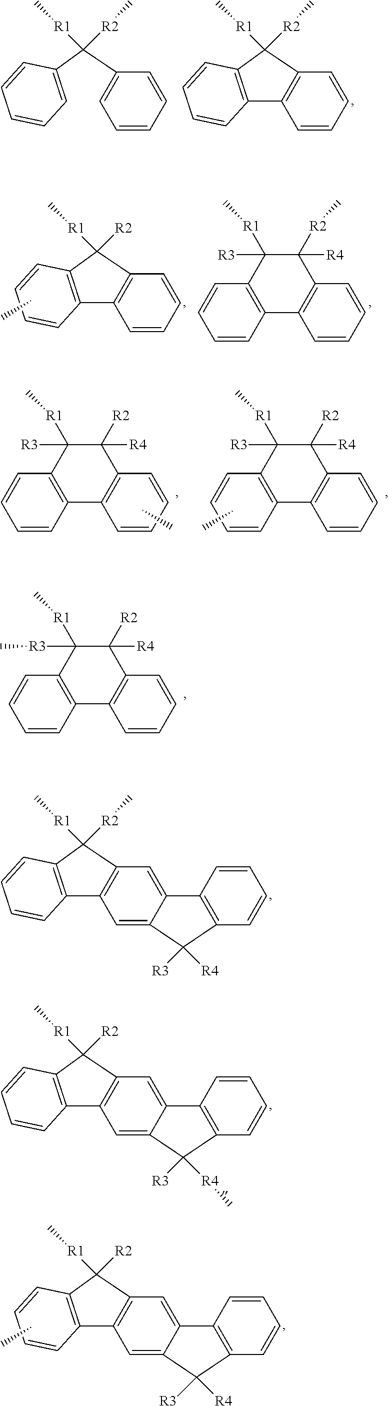

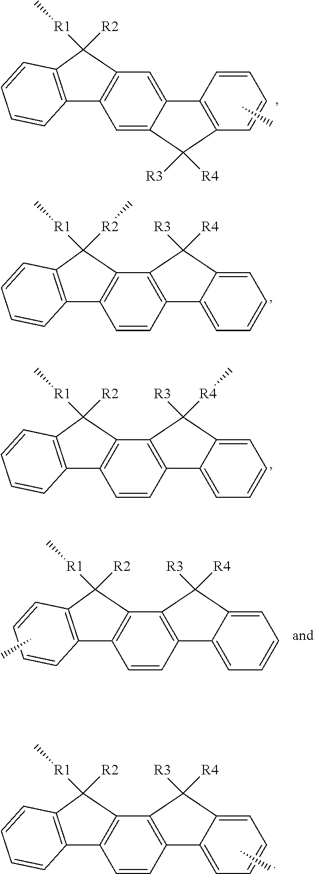

In one of the embodiments, the compound of the organic hole transporting layer material is one selected from following structures:

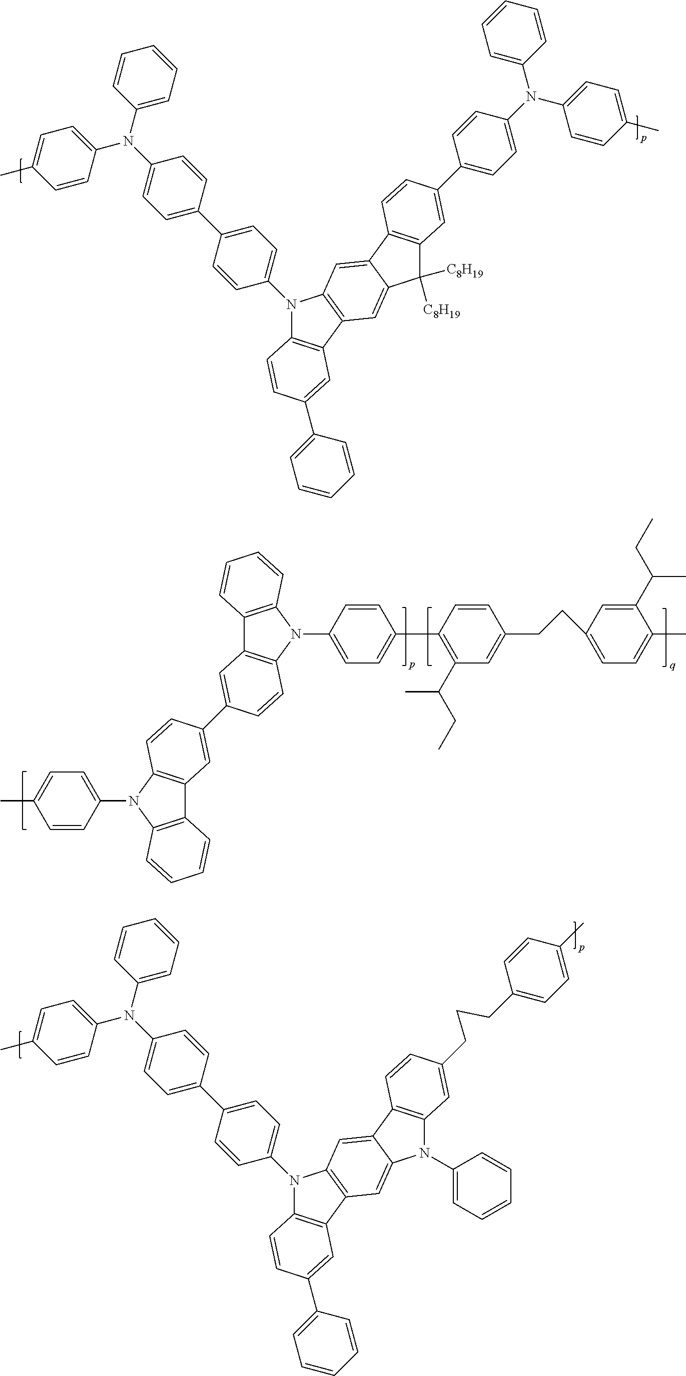

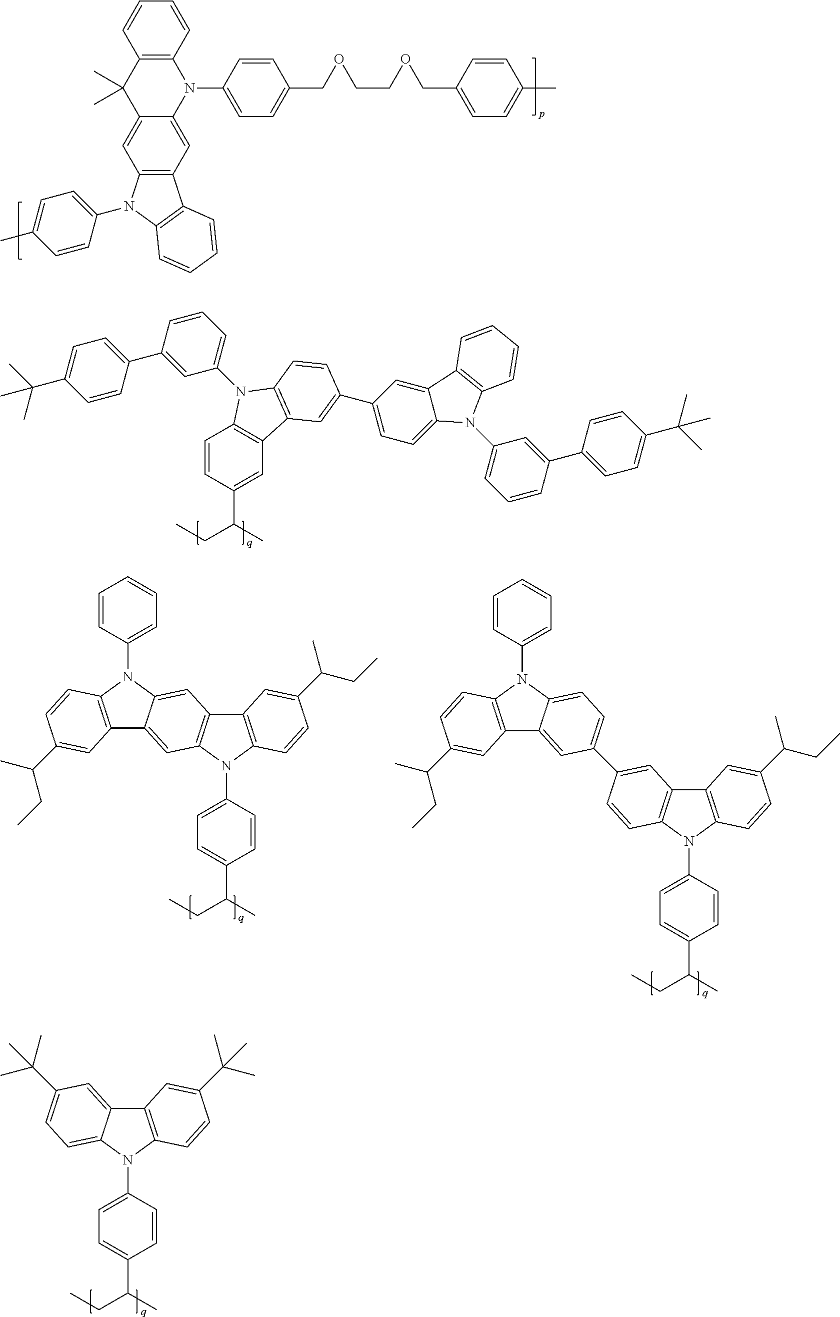

In one of the embodiments, the polymer hole transporting material has a relative molecular mass of ≥10000 g/mol.

In one of the embodiments, the polymer hole transporting material has a relative molecular mass of ≥50000 g/mol.

In one of the embodiments, the polymer hole transporting material has a relative molecular mass of ≥100000 g/mol.

In one of the embodiments, the polymer hole transporting material has a relative molecular mass of ≥200000 g/mol.

The hole transporting layer is prepared by vacuum evaporation, printing or coating.

In one of the embodiments, the hole transporting layer is prepared by printing or coating.

In one of the embodiments, printing or coating technique is at least one selected from the group consisting of inkjet printing, letterpress printing, screen printing, dip coating, spin coating, blade coating, roller printing, torsion roll printing, lithography, flexographic printing, rotary printing, spray coating, brush coating, or pad printing, slot die coating.

In one of the embodiments, the printing or coating technique is one selected from the group consisting of inkjet printing, screen printing, and gravure printing.

In one of the embodiments, the solution or suspension for printing includes at least one of the surface active compounds.

In one of the embodiments, the solution or suspension for printing includes at least one of a lubricant, a wetting agent, a dispersant, a hydrophobic agent, and an adhesive. For adjusting viscosity, film forming performance and improving adhesion. For more information about printing technologies and relevant requirements thereof on related solutions, such as solvents and concentration, viscosity, etc., see Handbook of Print Media: Technologies and Production Methods, ISBN 3-540-67326-1, edited by Helmut Kipphan.

The viscosity and surface tension of ink are important parameters when the ink is used in printing process. The surface tension parameters of suitable ink are suitable for a particular substrate and a particular printing method.

In one of the embodiments, the ink for preparing the hole transporting layer has a surface tension in the range of 19 dyne/cm to 50 dyne/cm at working temperature or at 25° C.

In one of the embodiments, the ink for preparing the hole transporting layer has a surface tension in the range of 22 dyne/cm to 35 dyne/cm at working temperature or at 25° C.

In one of the embodiments, the ink for preparing the hole transporting layer has a surface tension in the range of 25 dyne/cm to 33 dyne/cm at working temperature or at 25° C.

The viscosity can be adjusted by different methods, optionally adjusted by the selection of appropriate solvent and the concentration of functional materials in the ink.

In one of the embodiments, the ink for preparing the hole transporting layer has a viscosity in the range of 1 cps to 100 cps at working temperature or at 25° C.

In one of the embodiments, the ink for preparing the hole transporting layer has a viscosity in the range of 1 cps to 50 cps at working temperature or at 25° C.

In one of the embodiments, the ink for preparing the hole transporting layer has a viscosity in the range of 1.5 cps to 20 cps at working temperature or at 25° C.

In one of the embodiments, the ink for preparing the hole transporting layer has a viscosity in the range of 4.0 cps to 20 cps at working temperature or at 25° C.

The working temperature described above is from 15° C. to 30° C., further from 18° C. to 28° C., still further from 20° C. to 25° C., and even further from 23° C. to 25° C. The ink of the hole transporting layer so prepared is suitable for inkjet printing.

An ink for light-emitting layer includes an ink comprising a mixture of the inorganic luminescent nanomaterial described above and a polyimide high polymer, which facilitates adjustment of the printing ink in an appropriate viscosity range according to the printing method used, such as by the selection of appropriate solvent and concentration of functional materials in the ink.

In one of the embodiments, the mixture of the inorganic luminescent nanomaterial and the polyimide high polymer accounts for from 0.3 wt % to 30 wt % of the ink by weight.

In one of the embodiments, the mixture of the inorganic luminescent nanomaterial and the polyimide high polymer accounts for from 0.5 wt % to 20 wt % of the ink by weight.

In one of the embodiments, the mixture of the inorganic luminescent nanomaterial and the polyimide high polymer accounts for from 0.5 wt % to 15 wt % of the ink by weight.

In one of the embodiments, the mixture of the inorganic luminescent nanomaterial and the polyimide high polymer accounts for from 0.5 wt % to 10 wt % of the ink by weight.

In one of the embodiments, the mixture of the inorganic luminescent nanomaterial and the polyimide high polymer accounts for from 1 wt % to 5 wt % of the ink by weight.

In one of the embodiments, the organic solvent in the ink for the light-emitting layer is at least one selected from the group consisting of an aromatic solvent and a heteroaromatic solvent.

In one of the embodiments, the organic solvent in the ink for the light-emitting layer is at least one selected from the group consisting of an aliphatic chain-substituted aromatic solvent, an aliphatic ring-substituted aromatic solvent, an aliphatic chain-substituted aromatic ketone solvent, an aliphatic ring-substituted aromatic ketone solvent and an aliphatic chain-substituted aromatic ether solvent and an aliphatic ring-substituted aromatic ether solvent.

In one of the embodiments, an organic solvent based on aromatic or heteroaromatic is at least one selected from p-diisopropylbenzene, pentyl benzene, tetrahydronaphthalene, cyclohexylbenzene, chloronaphthalene, 1,4-dimethylnaphthalene, 3-isopropylbiphenyl, p-methylisopropylbenzene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-methylisopropylbenzene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene and dibenzyl ether.

In one of the embodiments, an organic solvent based on ketone is at least one selected from 1-tetralone, 2-tetralone, 2-(phenylepoxy)tetralone, 6-(methyloxy)tetralone, acetophenone, propiophenone, benzophenone, and derivatives thereof, such as 4-methylacetophenone, 3-methylacetophenone, 2-methylacetophenone, 4-methylpropiophenone, 3-methylpropiophenone, 2-methylpropiophenone, isophorone, 2,6,8-trimethyl-4-nonanone, fenchone, 2-nonanone, 3-nonanone, 5-nonanone, 2-decanone, 2,5-hexanedione, phorone and 6-undecanone.

In one of the embodiments, an aromatic ether solvent is at least one selected from 3-phenoxytoluene, butoxybenzene, benzyl butylbenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenyl anisole, 1,2-dimethoxybenzene, 1-methoxynaphthalene, diphenyl ether, 2-phenoxymethyl ether, 2-phenoxytetrahydrofuran, ethyl-2-naphthyl ether, amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethyl ether butyl methyl ether, tripropylene glycol dimethyl ether and tetraethylene glycol dimethyl ether.

In one of the embodiments, an ester solvent is at least one selected from the group consisting of alkyl caprylate, alkyl sebacate, alkyl stearate, alkyl benzoate, alkyl phenylacetate, alkyl cinnamate, alkyl oxalate, alkyl maleate, alkyl lactone and alkyl oleate.

In one of the embodiments, the organic solvent of the ink for the light-emitting layer is at least one selected from the group consisting of aliphatic ketone and aliphatic ether.

In one of the embodiments, the organic solvent of the ink for the light-emitting layer is at least one selected from the group consisting of 2-nonanone, 3-nonanone, 5-nonanone, 2-decanone, 2,5-hexanedione, 2,6,8-trimethyl-4-nonanone, phorone and 6-undecanone.

In one of the embodiments, the organic solvent of the ink is at least one selected from the group consisting of amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether and tetraethylene glycol dimethyl ether.

In one of the embodiments, the ink described above also includes another organic solvent.

In one of the embodiments, the other solvent may be at least one selected from the group consisting of methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxy toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin and indene.

In another embodiment, the electroluminescent device further includes an electron transporting layer (ETL) located between the cathode and the light-emitting layer.

In one of the embodiments, the electron transporting layer (ETL) contains an organic electron transporting material (ETM) or an inorganic n-type material.

In one of the embodiments, the electron transporting layer (ETL) is a metal complex or an organic compound capable of transporting electrons.

In one of the embodiments, the material of the electron transporting layer (ETL) is one selected from the group consisting of tris(8-hydroxyquinoline)aluminum (AlQ₃), phenazine, phenanthroline, anthracene, phenanthrene, fluorene, difluorene, spirobifluorene, p-phenylacetylene, pyridazine, pyrazine, triazine, triazole, imidazole, quinoline, isoquinoline, quinoxaline, oxazole, isoxazole, oxadiazole, thiadiazole, pyridine, pyrazole, pyrrole, pyrimidine, acridine, pyrene, perylene, trans-indenofluorene, cis-indeno, dibenzo-indenofluorene, indenonaphthalene, benzoanthracene, azaphosphole, azaborole, an aromatic ketone, lactam, a derivative of tris(8-hydroxyquinoline)aluminum (AlQ₃), a derivative of phenazine, a derivative of phenanthroline, a derivative of anthracene, a derivative of phenanthrene, a derivative of fluorene, a derivative of difluorene, a derivative of spirobifluorene, a derivative of p-phenylacetylene, a derivative of pyridazine, a derivative of pyrazine, a derivative of triazine, a derivative of triazole, a derivative of imidazole, a derivative of quinoline, a derivative of isoquinoline, a derivative of quinoxaline, a derivative of oxazole, a derivative of isoxazole, a derivative of oxadiazole, a derivative of thiadiazole, a derivative of pyridine, a derivative of pyrazole, a derivative of pyrrole, a derivative of pyrimidine, a derivative of acridine, a derivative of pyrene, a derivative of perylene, a derivative of a derivative of trans-indenofluorene, cis-indeno, a derivative of dibenzo-indenofluorene, a derivative of indenonaphthalene, a derivative of benzoanthracene, a derivative of azaphosphole, a derivative of azaborole, a derivative of an aromatic ketone, and a derivative of lactam.

In one of the embodiments, the material of the electron transporting layer (ETL) is an inorganic n-type semiconductor material.

In one of the embodiments, the material of the electron transporting layer (ETL) is at least one selected from the group consisting of a metal oxide, a Group IV semiconductor material, a Group III-V semiconductor material, a Group IV-VI semiconductor material, and a Group II-VI semiconductor material.

In one of the embodiments, the metal oxide is one selected from the group consisting of ZnO, In₂O₃, Ga₂O₃, TiO₂, MoO₃ and SnO₂.

In one of the embodiments, the material of the electron transporting layer (ETL) is at least one selected from the group consisting of a Group IV semiconductor, a Group III-V semiconductor, a Group IV-VI semiconductor, and a Group II-VI semiconductor and an alloy of metal oxides.

In one of the embodiments, the material of the electron transporting layer (ETL) is at least one selected from the group consisting of SnO₂:Sb, In₂O₃:Sn (ITO), ZnO:Al, Zn—Sn—O, In—Zn—O and IGZO.

In one of the embodiments, IGZO is one selected from the group consisting of InGaZnO₄, In₂Ga₂ZnO₇ and InGaZnOx.

In one of the embodiments, the electroluminescent device further includes an electron injection layer (EIL) located between the cathode and the electron transporting layer. It can be understood that the selection range of the material of the electron injection layer (EIL) is identical to the selection range of the material of the electron transporting layer (ETL).

The above electroluminescent device includes an organic hole transporting material between the anode and the light-emitting layer, wherein the organic hole transporting material has a HOMO energy level≤−5.4 eV and has a larger ΔHOMO value (≥0.3 eV), which effectively reduces the operating voltage of the device and improves luminous efficiency, meanwhile improves device lifetime and provides a solution of quantum dot luminescent device with high performance.

A polymer has the following structural formulas:

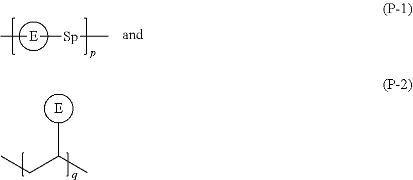

wherein p and q represent the number of repeating units, and both p and q are integers of ≥1;

HOMO_{E}≤−5.4 eV and □(HOMO−1)_{E}−HOMO_{E}□≥0.3 eV;

E is one of the following structures:

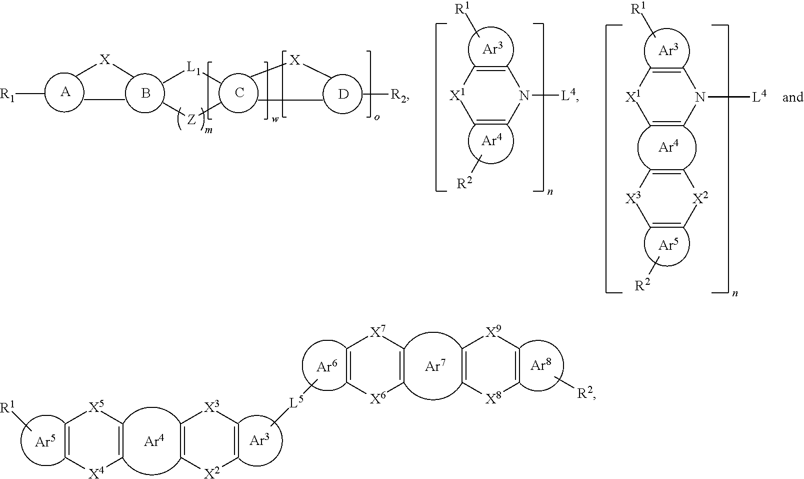

wherein -L₁- is a single bond or an arylene group containing 6 to 30 carbon atoms.

-L⁴- is an aryl group containing 5 to 60 carbon atoms or a heteroaryl group containing 5 to 60 carbon atoms.

-L⁵- is one selected from the group consisting of a single bond, an aryl group containing 5 to 30 carbon atoms, and a heteroaryl group containing 5 to 30 carbon atoms.

A, B, C, and D are each independently an aromatic ring containing 6 to 40 carbon atoms or a heteroaromatic ring containing 5 to 40 carbon atoms.

—X—, —Y—, and —Z— are each independently selected from the group consisting of —NR₁₁—, —CR₁₂R₁₃—, —O—, and —S—.

R₁, R₂, R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms.

m, w, and o are each independently 0 or 1.

Ar³, Ar⁴, Ar⁵, Ar⁶, Ar⁷, and Ar⁸ are each independently selected from the group consisting of an aryl group containing 5 to 40 carbon atoms, and a heteroaryl group containing 5 to 40 carbon atoms.

—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—,

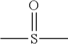

### and —SO₂—,

—X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—,

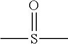

and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously; and in the general formula (IV), at least one of the —X²—, —X³—, —X⁴—, —X⁵—, —X⁶—, —X⁷—, —X⁸—, and —X⁹— is —N(R)—.

R¹, R², and R are each independently selected from the group consisting of H, D, F, CN, alkenyl, alkynyl, nitrile, amine, nitro, acyl, alkoxy, carbonyl, sulfonyl, and an alkyl group containing 1 to 30 carbon atoms, a cycloalkyl group containing 3 to 30 carbon atoms, an aromatic hydrocarbyl containing 6 to 60 carbon atoms, and an aromatic heterocyclyl group containing 5 to 60 carbon atoms; wherein attachment positions of R¹ and R² are carbon atoms on the fused ring. n is an integer of 0 to 4.

Sp is a non-conjugated spacer group.

When the polymer described above is applied to an electroluminescence device, the luminous efficiency and lifetime of the electroluminescent device can be improved.

The present embodiment will be described below with reference to the preferred examples, but the present embodiment is not limited to the following examples. It should be understood that the appended claims summarized the scope of the present embodiment. Those skill in the art should realize that certain changes to the examples of the present embodiment that are made under the guidance of the concept of the present embodiment will be covered by the spirit and scope of the claims of the present embodiment.

### DETAILED EXAMPLES

1. Materials and Energy Level Structure

The structural formulas of organic hole transporting material used in examples 1 to 5 are as follows:

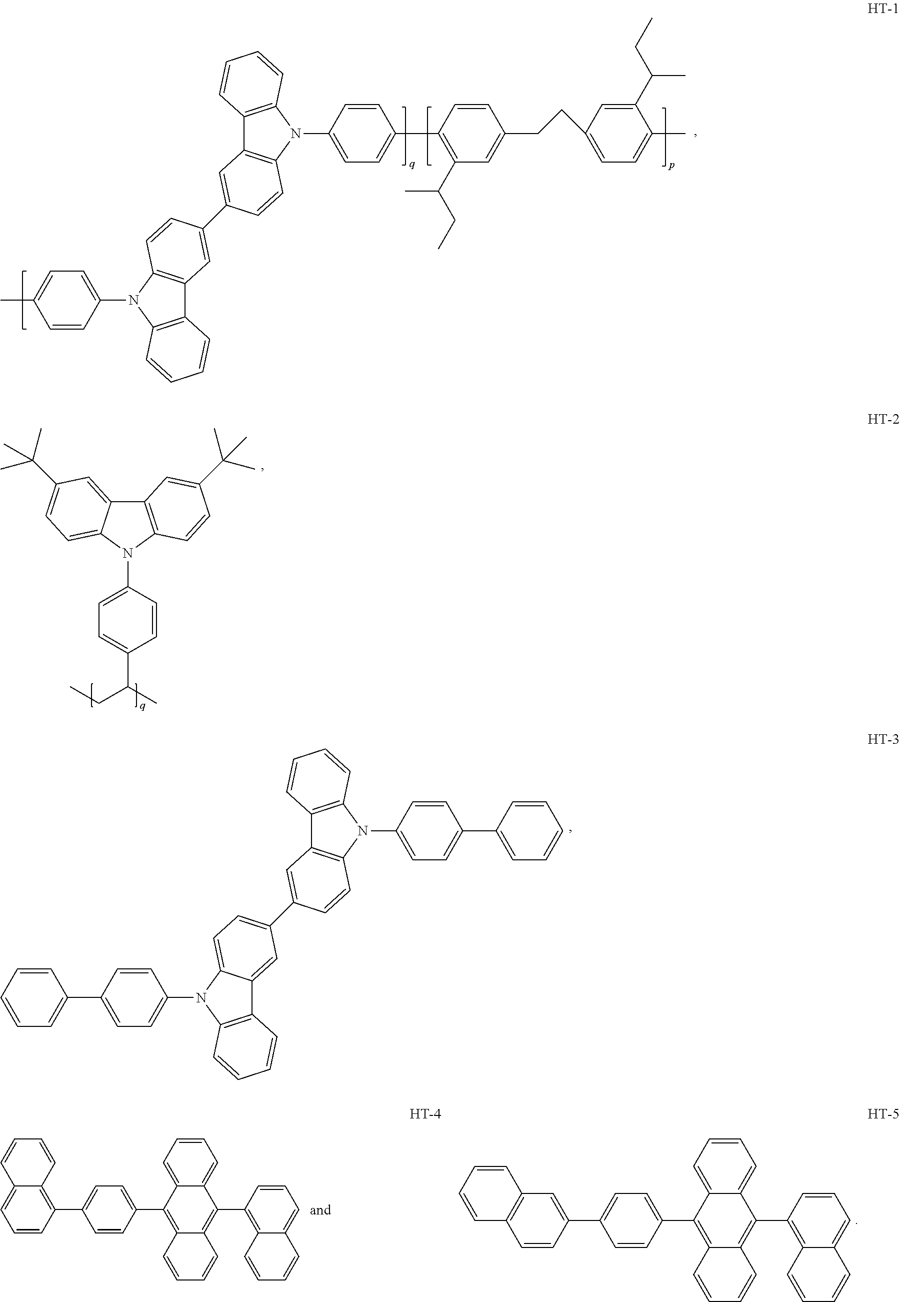

The synthesis steps of HT-1 are as follows:

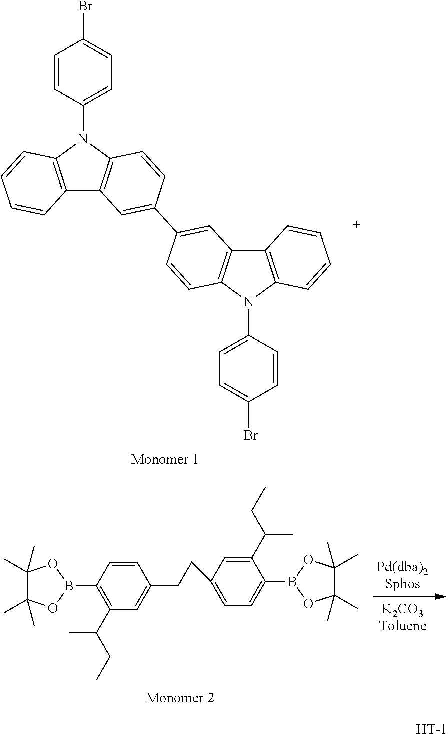

Monomer 1 and monomer 2 were added to a polymerization tube at a molar ratio of 1:1, with a mass respectively of: 0.75 g of monomer 1 (2.26 mmol) and 1.23 g of monomer 2 (2.26 mmol); meanwhile, 0.026 g of Pd(dba)₂ (0.045 mmol), 0.037 g of Sphos (0.090 mmol), 3.39 ml of 2 M potassium carbonate aqueous solution, and 5 ml of toluene were added, protected with nitrogen after fully pumping the gas, and the reaction was carried out at 100° C. for 24 hours without light. Thereafter, 0.1 ml of bromobenzene was added, and the reaction was carried out for 6 hours, and then 0.2 g of phenylboronic acid was further added thereto, and the reaction was carried out for 6 hours. After completion of the reaction, the polymer was obtained, cooled, and washed with deionized water for three times. After drying the organic phase, the polymer was quickly passed through a short silica gel column with a polarity of PE:DCM=2:1 (volume ratio). The polymer was dissolved in 50 ml of DCM, slowly poured into 200 ml of methanol to form filament, and then extracted with acetone for 24 hours, and the process of forming filament in methanol-extracting with acetone was repeated for three times. 1.18 g of polymer was obtained, with the yield of 67%, Mw=194813, PDI=1.98. p=50, q=50.

The synthesis steps of HT-2 are as follows:

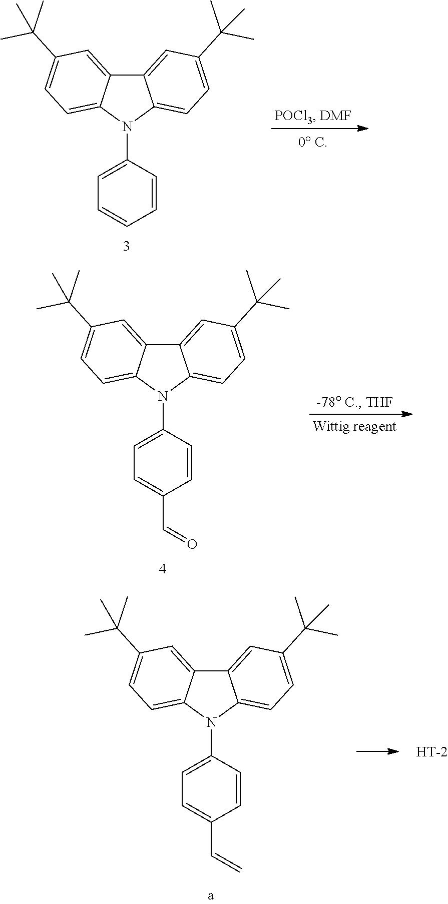

Under nitrogen protection, 9 mmol of compound 3 was dissolved in 250 ml of dry DMF solution, and the resulting reaction solution was placed in an ice bath and stirred, and 11.0 mmol of phosphorus oxychloride (POCl₃) solution was added dropwise. After compilation of the addition, the reaction was continued for 30 minutes, gradually warmed to room temperature and carried out for 2 hours. The reaction was quenched with water, extracted with methylene chloride, washed with water, and the organic phase was combined, dried with anhydrous sodium sulfate, filtered, and the organic solvent was evaporated to obtain a crude product of compound 4. The crude product was recrystallized with dichloromethane and n-hexane to obtain 7 mmol of product, which was dried in vacuum for further use.

The 5.0 mmol of the compound 4 obtained above was dissolved in 200 ml of dry tetrahydrofuran (THF) solution. Under the protection of nitrogen atmosphere, the reaction solution was stirred at a temperature of −78° C., 8.0 mmol of methylenetriphenylphosphorate (Wittig reagent) was added dropwise. After completion of the addition, the temperature was gradually raised to room temperature, continued to stir at room temperature overnight. Water was added to quench the reaction then reaction solution was obtained, and the reaction solution is extracted with dichloromethane, and organic phase was washed with water, the organic phase was finally combined, dried with aqueous sodium sulfate, filtered, and the organic solvent was evaporated. The product was purified with silica gel column, and the mobile phase was dichloromethane:petroleum ether=1:2 (volume ratio) to obtain 4.0 mmol of monomer finally, which was dried in a vacuum environment for further use.

Polymer Synthesis: A Shrek tube reactor with stirring function was cooled with liquid nitrogen. 10.2 g of monomer a and 1.8 mg of azobisisobutyronitrile (AIBN) were added to the reaction apparatus and protected with nitrogen. The reactor was then placed in an oil bath and stirred at 67° C., the reaction was carried out for 8 hours. After cooling, the solid in the apparatus was dissolved in 50 ml of DMF, and purified by sedimentation twice in 800 ml of methanol, and 10.0 g of HT-2 was obtained (yield 98%).

HT-3 was synthesized by reference to the method of WO200634125A1.

HT-4 and TH-5 were purchased from Jilin OLED Material Tech Co., Ltd.

PVK was purchased from Sigma Aldrich.

The energy level of organic materials can be obtained by quantum calculations, optionally using TD-DFT (Time Dependent-Density Functional Theory) by Gaussian09W (Gaussian Inc.), and the specific simulation methods can be found in WO2011141110. In the examples of the present embodiment, the molecular geometry is optimized by semi-empirical method “Ground State/Semi-empirical/Default Spin/AM1” (Charge 0/Spin Singlet), and then the energy structure of organic molecules is calculated by TD-DFT (time-density functional theory) “TD-SCF/DFT/Default Spin/B3PW91” and the basis set “6-31G (d)” (Charge 0/Spin Singlet). The HOMO and LUMO levels are calculated according to the following calibration formulas, S1 and T1 are used directly.

HOMO(eV)=((HOMO(G)×27.212)−0.9899)/1.1206

LUMO(eV)=((LUMO(G)×27.212)−2.0041)/1.385

wherein HOMO(G) and LUMO(G) in the unit of Hartree are the direct calculation results of Gaussian 09W. See WO2011141110 for specific simulation methods. Wherein, the polymers HT-1 and HT-2 are obtained by simulating the trimer:

TABLE 1

| | | HOMO − | | | |
|---|---|---|---|---|---|
| Material | HOMO [eV] | 1[eV] | LUMO [eV] | T1 [eV] | S1 [eV] |
| HT-1 | −5.45 | −5.88 | −2.07 | 2.94 | 3.57 |
| HT-2 | −5.74 | −6.12 | −2.04 | 3.11 | 3.99 |
| HT-3 | −5.43 | −5.84 | −2.24 | 2.90 | 3.11 |
| HT-4 | −5.57 | −6.08 | −2.70 | 1.71 | 3.17 |
| HT-5 | −5.54 | −6.11 | −2.70 | 1.71 | 3.15 |
| PVK | −5.81 | −6.08 | −2.00 | 3.12 | 4.03 |

2. Preparation and Performance Test of Electroluminescent Devices

The preparation process of the electroluminescent device mentioned above is described in detail with reference to the following concrete embodiments.

### Example 1

1) Cleaning of ITO transparent electrode (anode) glass substrate: ultrasonic treatment was performed for 30 minutes using aqueous solution of 5% Decon90 cleaning solution, followed by ultrasonic cleaning with deionized water, then ultrasonic cleaning with isopropanol and blowing dry with nitrogen; the treatment under oxygen plasma was for 5 minutes to clean the ITO surface and improve the work function of the ITO electrode.

2) Preparation of the hole transporting layer: the oxygen plasma-treated glass substrate was spin-coated with a PEDOT:PSS solution to obtain a thin film of 40 nm and annealed in air at 150° C. for 20 minutes after spin-coating, then a 20 nm of HT-1 thin film (5 mg/mL toluene solution) was obtained by spin-coating on the PEDOT:PSS layer, followed by treatment on a hot plate at 180° C. for 60 minutes.

3) Preparation of quantum dot light-emitting layer: after completion of the preparation of the hole transporting layer, quantum dot solution was spin-coated, wherein the quantum dot is CdSe/CdS core-shell structure, dispersed in n-octane, with solution concentration of 5 mg/mL, a 40 nm film was obtained by spin coating.

4) Preparation of electron transporting layer: after completion of the spin coating of the quantum dot solution, a layer of 40 nm ZnO ethanol solution was spin-coated, wherein ZnO in the ZnO ethanol solution was synthesized by low-temperature solution process, and the ZnO is a nanoparticle in the size of 5 nm dispersing in ethanol to form an ZnO ethanol solution with a concentration of 45 mg/mL.

5) Preparation of cathode: the spin-coated device was placed in a vacuum evaporation chamber, and a silver electrode of the cathode was deposited to complete a quantum dot luminescent device.

### Example 2

The preparation steps of the device are identical to those of Example 1, except that the organic hole transporting material uses HT-2 instead of HT-1.

### Example 3

The treatment steps of ITO transparent electrode (cathode) are identical to those of Example 1, thereafter a layer of 40 nm ZnO ethanol solution was spin-coated on the ITO glass, and then a 25 nm CdSe—ZnS—CdZnS quantum dot light-emitting layer (chlorobenzene solution) was obtained by spin-coating, then transferred to a vacuum evaporation chamber, and evaporated with 20 nm organic hole transporting material HT-3, 10 nm MoO₃ and 100 nm Al sequentially to complete a quantum dot luminescent device.

### Example 4

The preparation steps of the device are substantially identical to those of Example 3, with the difference that the organic hole transporting material uses HT-4 instead of HT-3.

### Example 5

The preparation steps of the device are substantially identical to those of Example 1, with the difference that the organic hole transporting material uses HT-5 instead of HT-3.

### Example 6 (Comparative Example)

The preparation steps of the device are substantially identical to those of Example 1, with the difference that the organic hole transporting material uses PVK instead of HT-3. PVK was purchased from Sigma Aldrich.

The properties of the electroluminescent devices in all of the examples are listed in Table 2.

TABLE 2

| | Driving | Maximum | Luminous | Lifetime @500 |
|---|---|---|---|---|
| | Voltage | luminance | peak | nits Relative |
| | (V) | cd/m² | (nm) | Comparative Example |
| Example 1 | 3.7 | 21000 | 618 | 221 |
| Example 2 | 4.2 | 14870 | 618 | 203 |
| Example 3 | 3.9 | 18000 | 619 | 351 |
| Example 4 | 4.05 | 19000 | 619 | 224 |
| Example 5 | 4.11 | 17520 | 620 | 232 |
| Comparative | 4.3 | 15000 | 618 | 100 |
| Example | | | | |

1. An electroluminescent device, comprising an anode, a cathode, a light-emitting layer located between the anode and the cathode, and a hole transporting layer located between the anode and the light-emitting layer, wherein the light-emitting layer comprises an inorganic luminescent nanomaterial, the hole transporting layer comprises an organic hole transporting material having a HOMO_{HTM}≤−5.4 eV and □(HOMO−1)_{HTM}−HOMO_{HTM}□≥0.3 eV, HOMO_{HTM} represents the highest occupied molecular orbital energy level, (HOMO−1)_{HTM} represents the second highest occupied molecular orbital energy level.

2. The electroluminescent device according to claim 1, wherein the hole transporting material comprises at least one of an organic small molecule and a polymer.

3. The electroluminescent device according to claim 1, wherein the organic hole transporting material comprises a small molecule hole transporting material containing the following general formula (I): 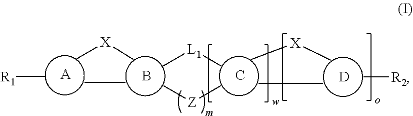
wherein -L₁- is a single bond or an arylene group containing 6 to 30 carbon atoms;
A, B, C, and D are each independently an aromatic ring containing 6 to 40 carbon atoms or a heteroaromatic ring containing 5 to 40 carbon atoms;
—X—, —Y—, and —Z— are each independently selected from the group consisting of —NR₁₁—, —CR₁₂R₁₃—, —O—, and —S—;
R₁, R₂, R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms;
m, w, and o are each independently 0 or 1.

4. The electroluminescent device according to claim 3, wherein the small molecule hole transporting material has one of the following general formulas (I-1) to (I-9): 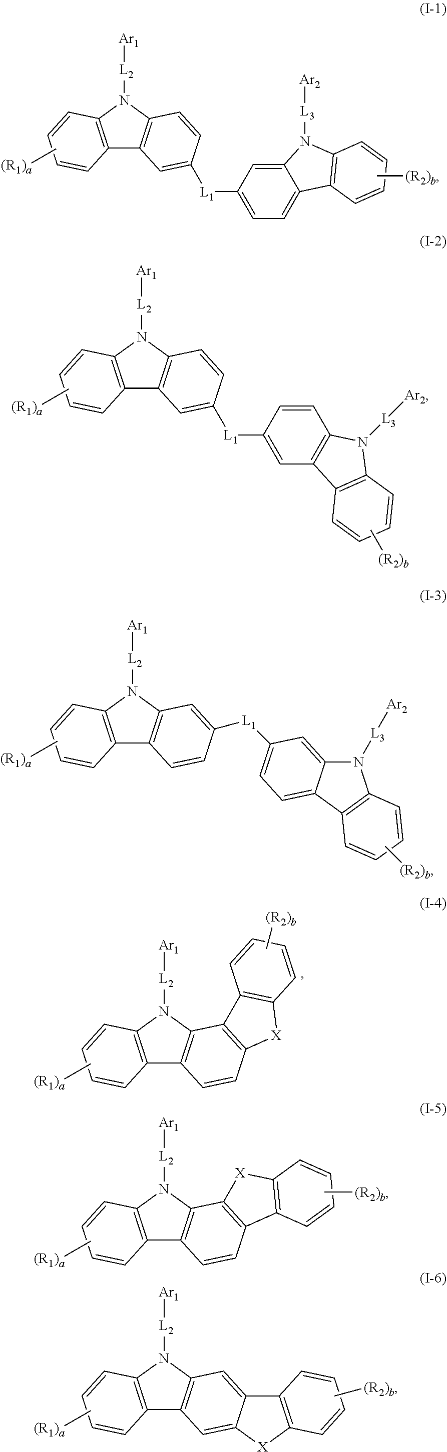 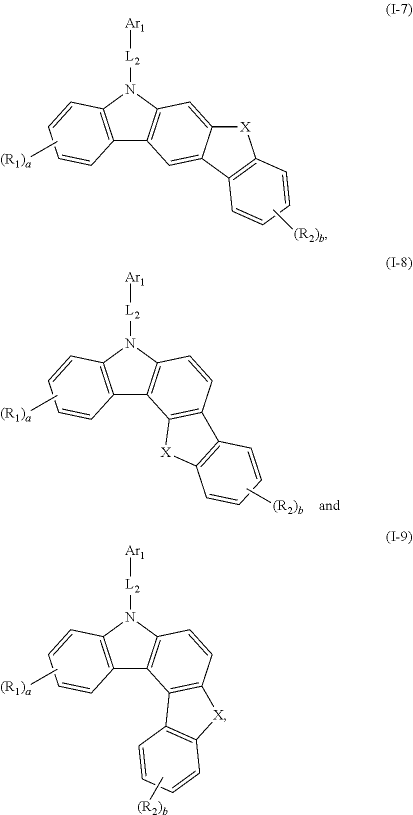
wherein -L²- and -L³- are each independently a single bond or an arylene group containing 6 to 40 carbon atoms;
a and b are each independently an integer of 0 to 4;
Ar₁ and Ar₂ are each independently selected from an aryl group and a heteroaryl group.

5. The electroluminescent device according to claim 1, wherein the organic hole transporting material comprises one of the compounds containing the following general formulas (II) to (IV): 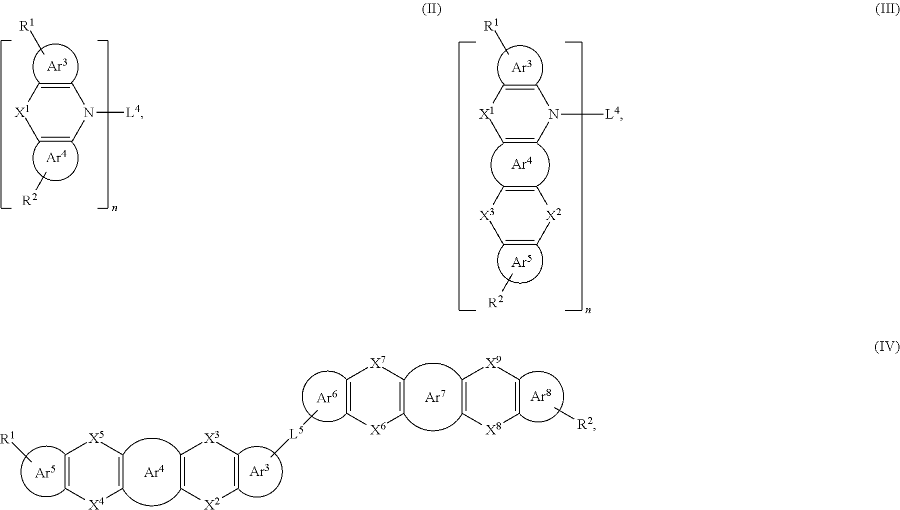
wherein L⁴ is an aryl group containing 5 to 60 carbon atoms or a heteroaryl group containing 5 to 60 carbon atoms;
-L⁵- is one selected from the group consisting of a single bond, an aryl group containing 5 to 30 carbon atoms, and a heteroaryl group containing 5 to 30 carbon atoms;
Ar³, Ar⁴, Ar⁵, Ar⁶, Ar⁷, and Ar⁸ are each independently selected from the group consisting of an aryl group containing 5 to 40 carbon atoms, and a heteroaryl group containing 5 to 40 carbon atoms;
—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—, 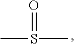
and —SO₂—;
—X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—, 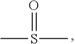
and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously;
and in the general formula (IV), at least one of the —X²—, —X³—, —X⁴—, —X⁵—, —X⁶—, —X⁷—, —X⁸—, and —X⁹— is —N(R)—;
R¹, R², and R are each independently selected from the group consisting of H, D, F, CN, alkenyl, alkynyl, nitrile, amine, nitro, acyl, alkoxy, carbonyl, sulfonyl, and an alkyl group containing 1 to 30 carbon atoms, an aromatic hydrocarbyl group containing 6 to 60 carbon atoms, and an aromatic heterocyclyl group containing 5 to 60 carbon atoms;
n represents an integer from 1 to 4.

6. The electroluminescent device according to claim 5, wherein the organic hole transporting material has one of the following structures: 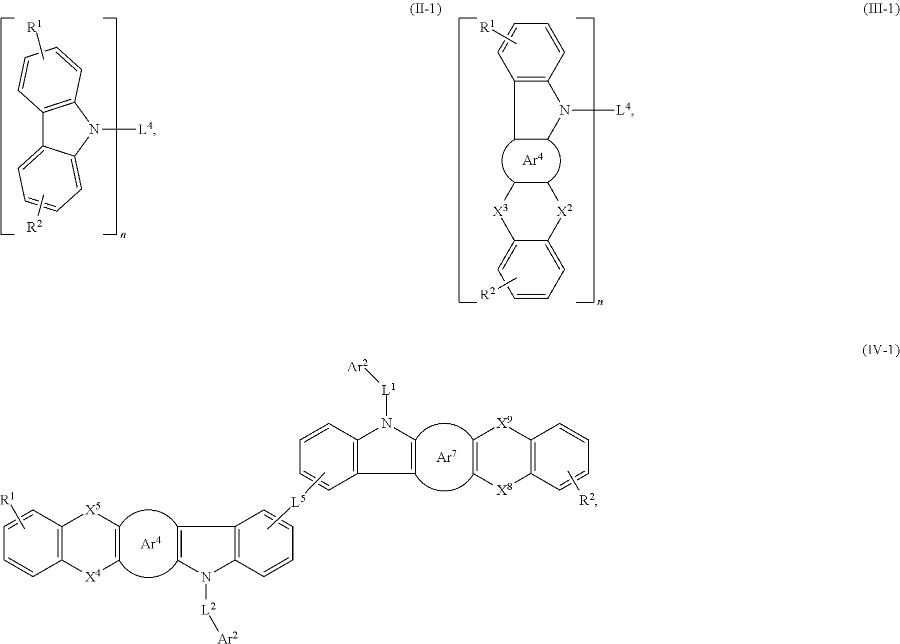
-L₁- is a single bond or an arylene group containing 6 to 30 carbon atoms;
-L²- is one selected from the group consisting of a single bond and an arylene group containing 6 to 40 carbon atoms;
Ar² is one selected from the group consisting of an aryl group containing 5 to 40 carbon atoms, and a heteroaryl group containing 5 to 40 carbon atoms;

7. The electroluminescent device according to claim 1, wherein the organic hole transporting material is at least one selected from the group consisting of the following compounds:

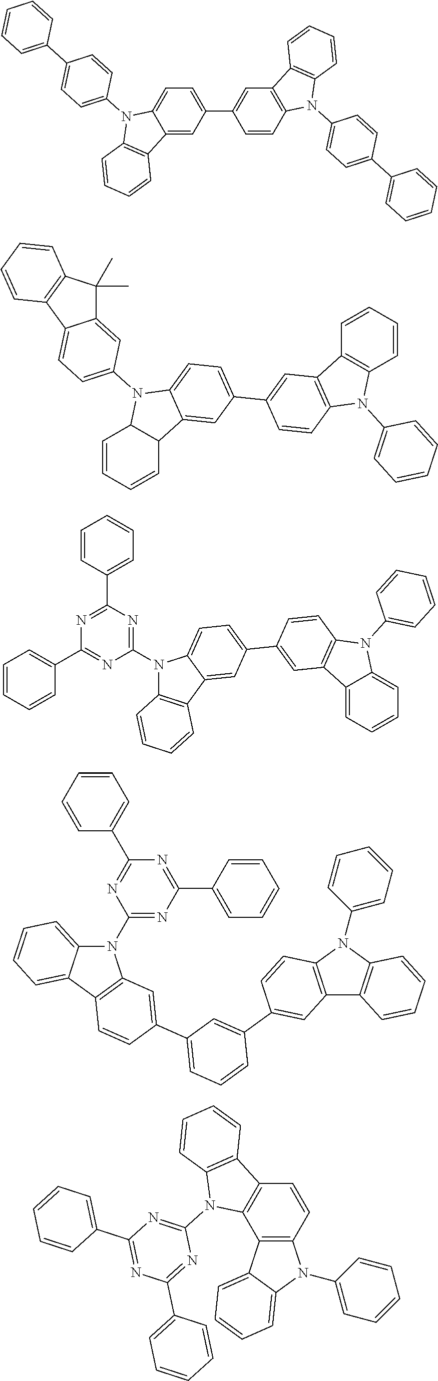

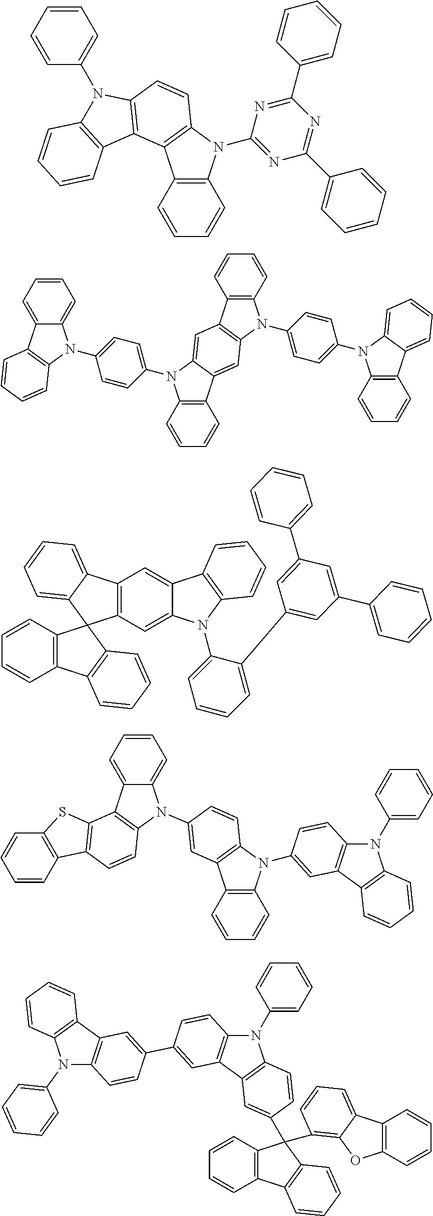

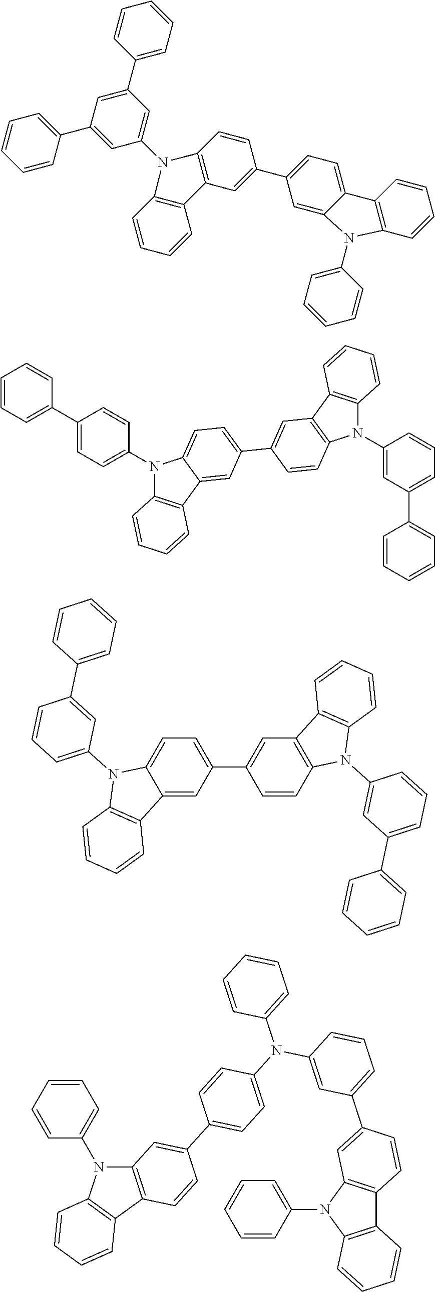

8. The electroluminescent device according to claim 1, wherein the organic hole transporting material is one selected from the group consisting of the compounds containing the following structures: 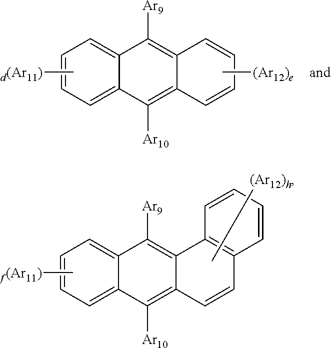
wherein Ar⁹ and Ar¹⁰ are each independently selected from the group consisting of an aryl group containing 6 to 60 carbon atoms, a heteroaryl group containing 3 to 60 carbon atoms;
Ar¹¹ and Ar¹² are each independently selected from the group consisting of H, D, F, —CN, —NO₂, —CF₃, alkenyl, alkynyl, amino, acyl, amide, cyano, isocyano, alkoxy, hydroxy, carbonyl, sulfonyl, an alkyl group containing 1 to 60 carbon atoms, an aryl group containing 6 to 60 carbon atoms, a heterocyclic aryl group containing 3 to 60 carbon atoms, and a fused ring aryl group containing 7 to 60 carbon atoms, or a fused heterocyclic aryl group containing 4 to 60 carbon atoms;
d, e, and f are each independently an integer from 0 to 4, and h is an integer from 0 to 6.

9. The electroluminescent device according to claim 1, wherein the organic hole transporting material comprises a polymer hole transporting material, the polymer hole transporting material comprises at least one containing the following general formula (P-1) to (P-2): 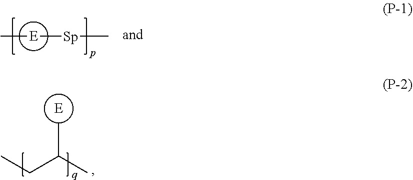
wherein p and q represent the number of repeating units, and both p and q are integers of ≥1;
HOMO_{E}≤−5.4 eV and □(HOMO−1)_{E}−HOMO_{E}□≥0.3 eV;
E is one of the following structures: 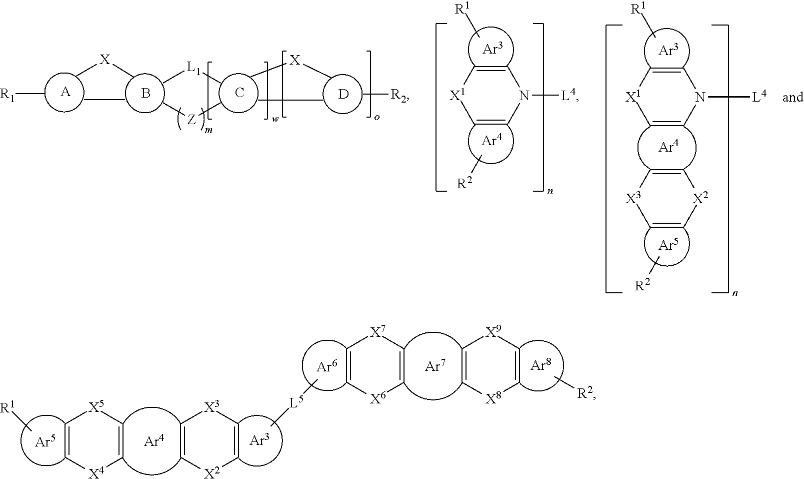
wherein -L₁- is a single bond or an arylene group containing 6 to 30 carbon atoms;
L⁴- is an aryl group containing 5 to 60 carbon atoms or a heteroaryl group containing 5 to 60 carbon atoms;
-L⁵- is one selected from the group consisting of a single bond, an aryl group containing 5 to 30 carbon atoms, and a heteroaryl group containing 5 to 30 carbon atoms;
A, B, C, and D are each independently an aromatic ring containing 6 to 40 carbon atoms or an heteroaromatic ring containing 5 to 40 carbon atoms;
—X—, —Y—, and —Z— are each independently selected from the group consisting of —NR₁₁—, —CR₁₂R₁₃—, —O—, and —S—;
R₁, R₂, R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms;
m, w, and o are each independently 0 or 1;
Ar³, Ar⁴, Ar⁵, Ar⁶, Ar⁷, and Ar⁸ are each independently selected from an aryl group containing 5 to 40 carbon atoms, and a heteroaryl group containing 5 to 40 carbon atoms;
—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—, 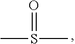
and —SO₂—;
—X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—, 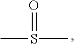
and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously; and in the general formula (IV), at least one of the —X²—, —X³—, —X⁴—, —X⁵—, —X⁶—, —X⁷—, —X⁸—, and —X⁹— is —N(R)—;
R¹, R² and R are each independently selected from the group consisting of H, D, F, CN, alkenyl, alkynyl, nitrile, amine, nitro, acyl, alkoxy, carbonyl, sulfonyl, and an alkyl group containing 1 to 30 carbon atoms, an aromatic hydrocarbyl group containing 6 to 60 carbon atoms, and an aromatic heterocyclyl group containing 5 to 60 carbon atoms; wherein attachment positions of R¹ and R² are carbon atoms on the fused ring;
n is an integer of 0 to 4;
Sp is a non-conjugated spacer group.

10. The electroluminescent device according to claim 9, wherein Sp is selected from the group consisting of a linear alkyl group containing 1 to 20 carbon atoms and a branched alkyl group containing 1 to 20 carbon atoms, wherein non-adjacent carbon atoms in the linear alkyl group and the branched alkyl group are substituted by O, S, NR₁₁, CR₁₂R₁₃, C(═O) or COO.

11. The electroluminescent device according to claim 1, wherein the inorganic luminescent nanomaterial is a quantum dot material, and the particle size of the inorganic luminescent nanomaterial has a monodisperse size distribution, and the shape of the inorganic luminescent nanomaterial is at least one selected from the group consisting of sphere, cube, rod, and branched structure.

12. The electroluminescent device according to claim 1, wherein the inorganic luminescent nanomaterial is at least one selected from the group consisting of a compound semiconductor of Group IV, a compound semiconductor of Group II-VI, and a compound semiconductor of Group II-V, a compound semiconductor of Group III-V, a compound semiconductor of Group III-VI, a compound semiconductor of Group IV-VI, a compound semiconductor of Group I-III-VI, a compound semiconductor of Group II-IV-VI, and a compound semiconductor of Group II-IV-V of the periodic table.

13. The electroluminescent device according to claim 1, wherein the inorganic luminescent nanomaterial is at least one selected from the group consisting of a light-emitting perovskite nanoparticle material, a metal nanoparticle material, and a metal oxide nanoparticle material.

14. The electroluminescent device according to claim 1, wherein the hole transporting layer is prepared by vacuum evaporation, printing or coating, wherein the printing is selected from the group consisting of ink jet printing, spray printing, letterpress printing, screen printing, roller printing, torsion roll printing, lithography, flexography, rotary printing, and pad printing, the coating is selected from the group consisting of dip coating, spin coating, blade coating, spray coating, brush coating and slot die coating.

15. A polymer having one of the following general formulas: 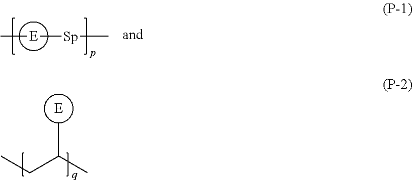
wherein p and q represent the number of repeating units, and both p and q are integers of ≥1;
HOMO_{E}≤−5.4 eV and □(HOMO−1)_{E}−HOMO_{E}≥0.3 eV;
E is one of the following structures: 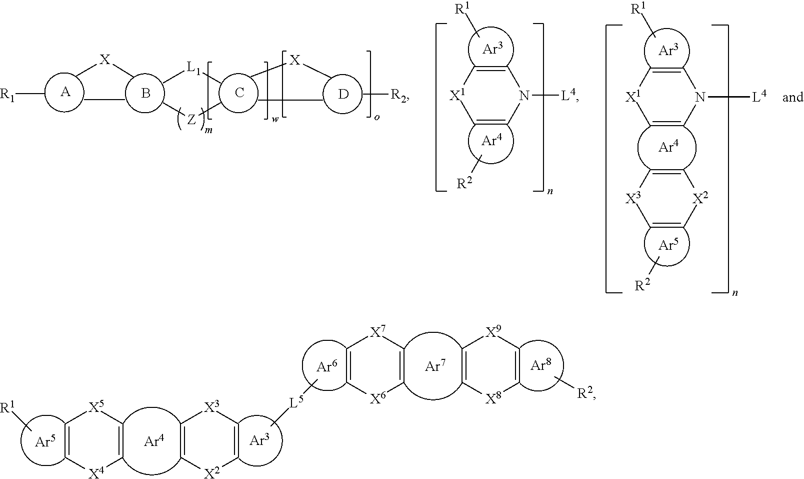
wherein -L₁- is a single bond or an arylene group containing 6 to 30 carbon atoms;
-L⁴- is an aryl group containing 5 to 60 carbon atoms or a heteroaryl group containing 5 to 60 carbon atoms;
-L⁵- is one selected from the group consisting of a single bond, an aryl group containing 5 to 30 carbon atoms, and a heteroaryl group containing 5 to 30 carbon atoms;
A, B, C, and D are each independently an aromatic ring containing 6 to 40 carbon atoms or an heteroaromatic ring containing 5 to 40 carbon atoms;
—X—, —Y—, and —Z— are each independently selected from the group consisting of —NR₁₁—, —CR₁₂R₁₃—, —O—, and —S—;
R₁, R₂, R₁₁, R₁₂, and R₁₃ are each independently selected from the group consisting of hydrogen, deuterium, an alkyl group containing 1 to 30 carbon atoms, an aryl group containing 6 to 30 carbon atoms, and a heteroaryl group containing 5 to 30 carbon atoms;
m, w, and o are each independently 0 or 1;
Ar³, Ar⁴, Ar⁵, Ar⁶, Ar⁷, and Ar⁸ are each independently selected from an aryl group containing 5 to 40 carbon atoms, and a heteroaryl group containing 5 to 40 carbon atoms;
—X¹— is one selected from the group consisting of a single bond, —N(R)—, —C(R)₂—, —Si(R)₂—, —O—, —C═N(R)—, —C═C(R)₂—, —P(R)—, —P(═O)R—, —S—, 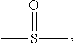
and —SO₂—;
X²—, —X³—, —X⁴—, —X⁵—, —X⁶—, —X⁷—, —X⁸—, and —X⁹— are each independently selected from the group consisting of a single bond, —N(R)—, —C(R)₂—, —Si(R)₂—, —O—, —C═N(R)—, —C═C(R)₂—, —P(R)—, —P(═O)R—, —S—, 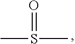
and —SO₂—, and —X²— and —X³— are not single bonds simultaneously, —X⁴— and —X⁵— are not single bonds simultaneously, —X⁶— and —X⁷— are not single bonds simultaneously, and —X⁸— and —X⁹— are not single bonds simultaneously; and in the general formula (IV), at least one of the —X²—, —X³—, —X⁴—, —X⁵—, —X⁶—, —X⁷—, —X⁸—, and —X⁹— is —N(R)—;
R¹, R² and R are each independently selected from the group consisting of H, D, F, CN, alkenyl, alkynyl, nitrile, amine, nitro, acyl, alkoxy, carbonyl, sulfonyl, and an alkyl group containing 1 to 30 carbon atoms, an aromatic hydrocarbyl group containing 6 to 60 carbon atoms, and an aromatic heterocyclyl group containing 5 to 60 carbon atoms; wherein attachment positions of R¹ and R² are carbon atoms on the fused ring;
n is an integer of 0 to 4;
Sp is a non-conjugated spacer group.

16. The electroluminescent device according to claim 3, wherein A, B, C, and D include one of the following structural groups: 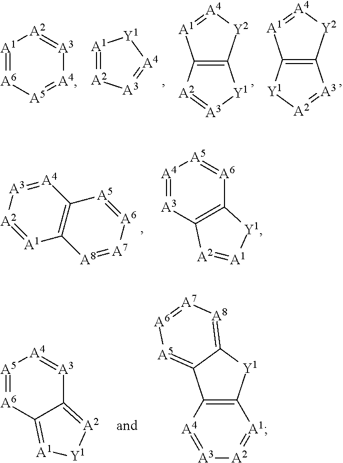
wherein A¹, A², A³, A⁴, A⁵, A⁶, A⁷, and A⁸ are each independently selected from CR³ and N,
Y¹, Y² are each independently selected from the group consisting of CR⁴R⁵, SiR⁴R⁵, NR³, C(═O), S, and O,
R³, R⁴, and R⁵ are each selected from of the group consisting of H, D, a linear alkyl group containing 1 to 20 carbon atoms, an alkoxy group containing 1 to 20 carbon atoms, a thioalkoxy group containing 1 to 20 carbon atoms, a branched alkyl group containing 3 to 20 carbon atoms, a cyclic alkyl group containing 3 to 20 carbon atoms, a silyl group containing 3 to 20 carbon atoms, a carbonyl group containing 1 to 20 carbon atoms, an alkoxycarbonyl group containing 2 to 20 carbon atoms, an aryloxycarbonyl group containing 7 to 20 C atoms, a cyano group (—CN), a carbamoyl group (—C(═O)NH₂), a halocarbonyl group (C(═O)—X, wherein X represents a halogen atom), a formyl group (—C(═O)—H), an isocyano group, an isocyanate group, a thiocyanate group, an isothiocyanate group, hydroxyl group, nitro group, a CF₃ group, Cl, Br, F, a crosslinkable group, an aryl group containing 5 to 40 carbon atoms, a heteroaromatic ring system containing 5 to 40 carbon atoms, an aryloxy containing 5 to 40 carbon atoms and a heteroaryloxy containing 5 to 40 carbon atoms. Wherein one or more groups of the R³, R⁴ and R⁵ can form a monocyclic or polycyclic aliphatic or aromatic ring with each other and/or with a ring bonded to the group.

17. The electroluminescent device according to claim 6, wherein Ar³, Ar⁴, Ar⁵, Ar⁶, Ar⁷, and Ar⁸ include one of the following structural groups: 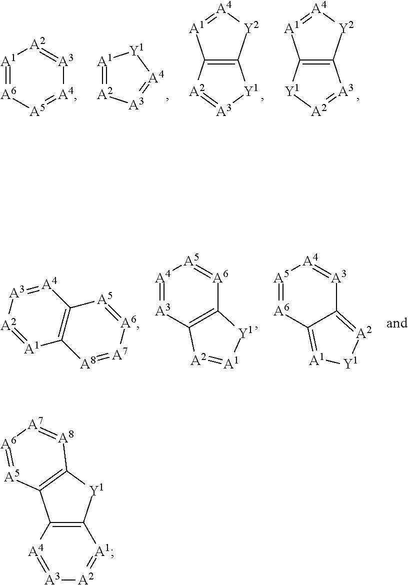
wherein A¹, A², A³, A⁴, A⁵, A⁶, A⁷, and A⁸ are each independently selected from CR³ and N,
Y¹, Y² are each independently selected from the group consisting of CR⁴R5, SiR⁴R⁵, NR³, C(═O), S, and O,
R³, R⁴, and R⁵ are each selected from of the group consisting of H, D, a linear alkyl group containing 1 to 20 carbon atoms, an alkoxy group containing 1 to 20 carbon atoms, a thioalkoxy group containing 1 to 20 carbon atoms, a branched alkyl group containing 3 to 20 carbon atoms, a cyclic alkyl group containing 3 to 20 carbon atoms, a silyl group containing 3 to 20 carbon atoms, a carbonyl group containing 1 to 20 carbon atoms, an alkoxycarbonyl group containing 2 to 20 carbon atoms, an aryloxycarbonyl group containing 7 to 20 C atoms, a cyano group (—CN), a carbamoyl group (—C(═O)NH₂), a halocarbonyl group (C(═O)—X, wherein X represents a halogen atom), a formyl group (—C(═O)—H), an isocyano group, an isocyanate group, a thiocyanate group, an isothiocyanate group, hydroxyl group, nitro group, a CF₃ group, Cl, Br, F, a crosslinkable group, an aryl group containing 5 to 40 carbon atoms, a heteroaromatic ring system containing 5 to 40 carbon atoms, an aryloxy containing 5 to 40 carbon atoms and a heteroaryloxy containing 5 to 40 carbon atoms. Wherein one or more groups of the R³, R⁴ and R⁵ can form a monocyclic or polycyclic aliphatic or aromatic ring with each other and/or with a ring bonded to the group.

18. The electroluminescent device according to claim 1, wherein the hole transporting material comprises an organic hole transporting material having a LUMO_{HTM}≥−4.5 eV, LUMO_{HTM} represents the lowest unoccupied molecular orbital energy level.

19. The electroluminescent device according to claim 11, wherein the polymer hole transporting material is one selected from the following structures:

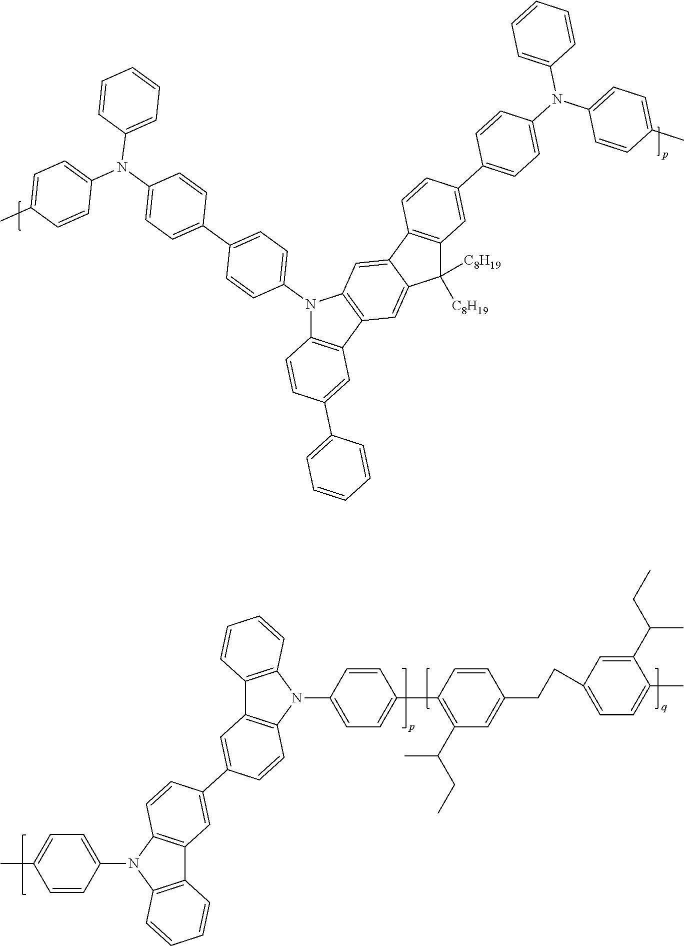

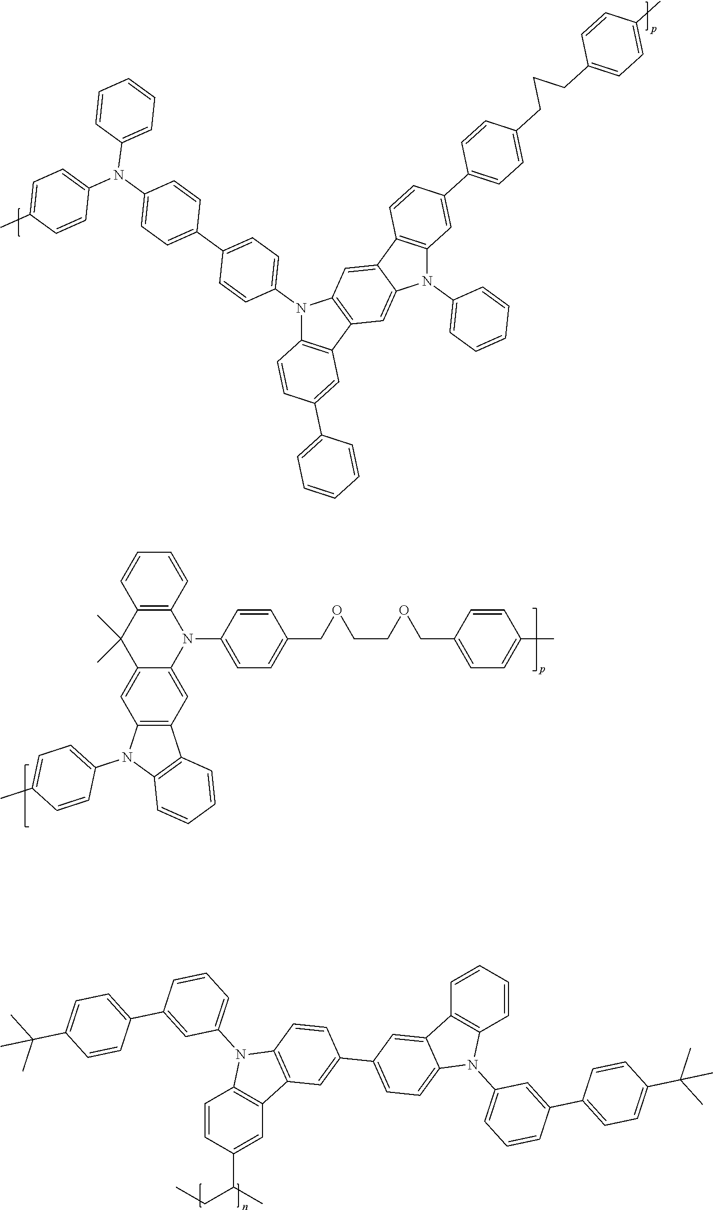

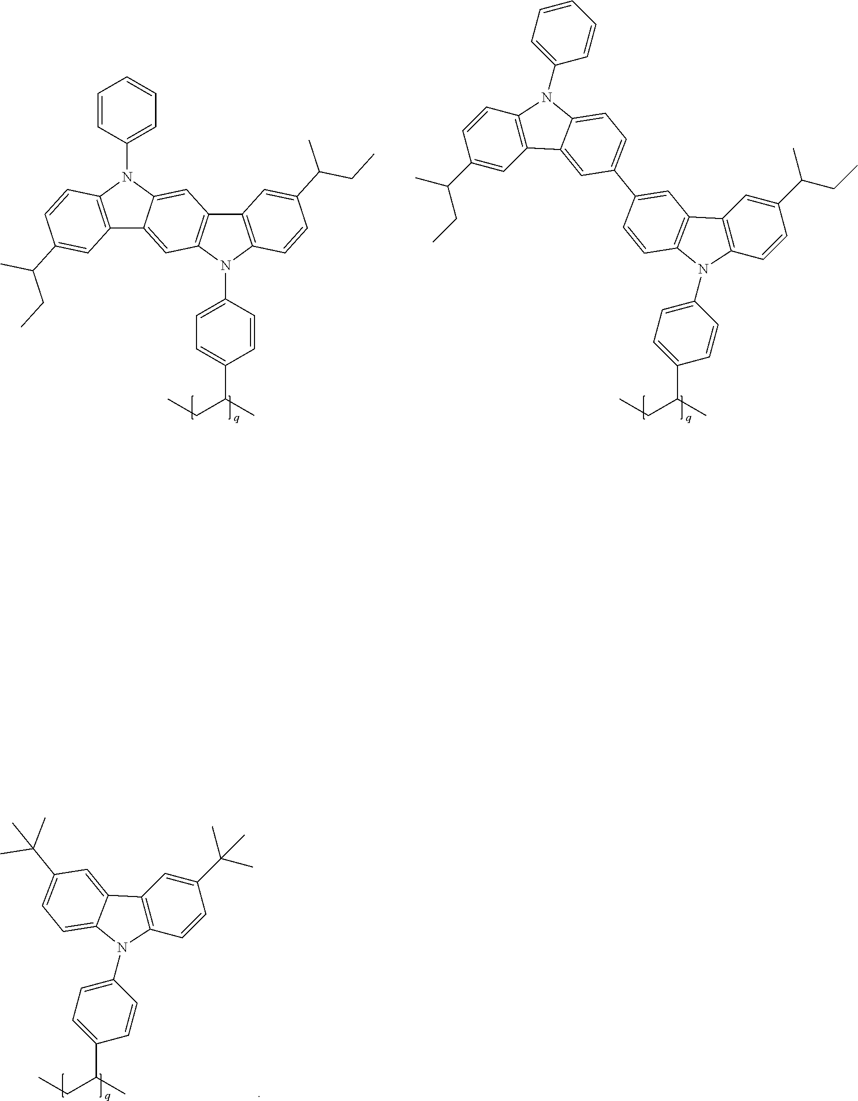

20. A polymer according to claim 19, wherein E is one of the following structures: 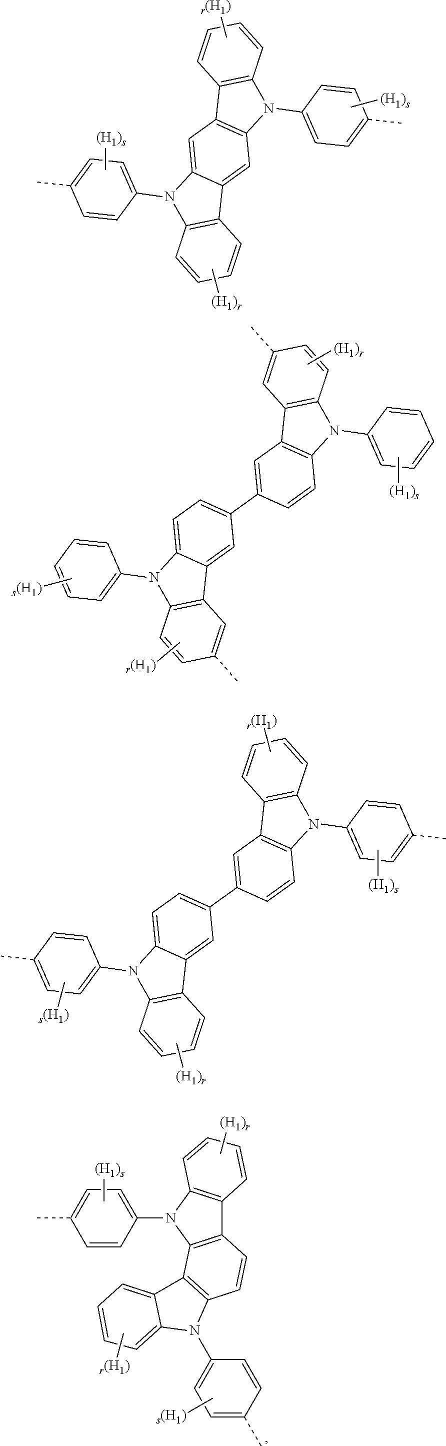
wherein, [symbol] represents a bond bonded to the group,
H₁ is at least one selected from of the group consisting of H, D, a linear alkyl group containing 1 to 20 carbon atoms, an alkoxy group containing 1 to 20 carbon atoms, a thioalkoxy group containing 1 to 20 carbon atoms, a branched alkyl group containing 3 to 20 carbon atoms, a cyclic alkyl group containing 3 to 20 carbon atoms, a silyl group containing 3 to 20 carbon atoms, a carbonyl group containing 1 to 20 carbon atoms, an alkoxycarbonyl group containing 2 to 20 carbon atoms, an aryloxycarbonyl group containing 7 to 20 C atoms, a cyano group (—CN), a carbamoyl group (—C(═O)NH₂), a halocarbonyl group (C(═O)—X, wherein X represents a halogen atom), a formyl group (—C(═O)—H), an isocyano group, an isocyanate group, a thiocyanate group, an isothiocyanate group, hydroxyl group, nitro group, a CF₃ group, Cl, Br, F, a crosslinkable group, an aryl group containing 5 to 40 carbon atoms, a heteroaromatic ring system containing 5 to 40 carbon atoms, an aryloxy containing 5 to 40 carbon atoms and a heteroaryloxy containing 5 to 40 carbon atoms. Wherein one or more groups of the R³, R⁴, and R⁵ can form a monocyclic or polycyclic aliphatic or aromatic ring with each other and/or with a ring bonded to the group,
r is 0, 1, 2, 3, or 4,
s is 0, 1, 2, 3, 4, or 5.
